(19) United States
(12) Patent Application Publication
(10) Pub. No.: US 2003/0177975 A1
(43) Pub. Date: Sep. 25, 2003

(54) Rare earth-iron garnet single crystal material and method for preparation thereof and device using rare earth-iron garnet single crystal material

(76) Inventors: Akio Ikesue, Nagoya-shi, Aichi (JP); Shinichi Kakita, Kobe-shi, Hyogo (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/380,689

(22) PCT Filed: Sep. 18, 2001
(86) PCT No.: PCT/JP01/08102

(30) Foreign Application Priority Data
Sep. 18, 2000 (JP) 2000-281682

(51) Int. Cl. C30B 1/00; C30B 29/10

(52) U.S. Cl. 117/2; 117/937

(57) ABSTRACT

An object of the present invention is to efficiently provide a high-quality rare-earth iron garnet single crystal. The invention relates to a rare-earth iron garnet single crystal substantially composed of an Re₃Fe₅₋ₓMₓO₁₂ single crystal (where Re is at least one element selected from Y, Bi, Ca, and lanthanide rare-earth elements with atomic numbers of 62 to 71; M is at least one element selected from Al, Ga, Sc, In, Sn and transition metal elements with atomic numbers of 22 to 30; and 0≦x<5), with the number per unit surface area (grains/cm²) of crystal grains that form low-angle tilt boundaries equal to 0≦n≦10²; and also relates to a device in which this rare-earth iron garnet single crystal is used.

### TECHNICAL FIELD

The present invention relates to a rare-earth iron garnet single crystal and a manufacturing method thereof.

### BACKGROUND ART

Re₃Fe₅O₁₂ single crystals (where Re is at least one element selected from the group consisting of Y, Bi, and lanthanide rare-earth elements with atomic numbers of 62 to 71) and the like are magnetooptic crystals widely used in isolators for optical communication, microwave resonators, magnetic bubble memory, optical switches, optical transducers, magneto-optics sensors, magneto-optics memory, high-frequency magnetic filters for mobile telephones, and the like.

As is evident from phase diagrams, it is difficult to directly form such single crystals from melts composed of Re₃Fe₅O₁₂, so these single crystals are manufactured by a flux technique in which a fluoride or chloride is the principal component of the flux, or by a top-seeded solution growth (TSSG) or floating zone (FZ) technique in which single crystals of Re₃Fe₅O₁₂ are directly pulled by forming a melt composition rich in Fe₂O₃. With these production techniques, it is difficult to manufacture large single crystals, and problems are encountered in that the resulting single crystals have high dislocation density, that the composition is likely to become nonuniform, and the like. For example, the flux technique commonly produces Re₃Fe₅O₁₂ single crystals measuring several millimeters or less, whereas the FZ technique can produce crystals that measure only 5 to 10 mm in diameter and about 50 to 60 mm in length. In addition, the TSSG technique has low manufacturing efficiency and high manufacturing costs because this technique uses an expensive noble metal crucible and has a growth rate of about 0.1 to 0.5 mm/h. In terms of the performance of the resulting single crystals, these methods are also disadvantageous in that, for example, impurities tend to be admixed during single crystal growth.

There is also a liquid phase epitaxial (LPE) technique for growing a magnetic garnet thick film on a nonmagnetic single crystal wafer with a relatively close lattice constant, but using an expensive nonmagnetic garnet wafer (commonly based on GGG: Gd₃Ga₅O₁₂) is a prerequisite, and 2 to 4 days (at a crystal growth rate of about 7 μm/h) are needed to form a magnetic garnet thick film (commonly about 0.5 mm) required as an isolator on this wafer. Another feature of this method is that the nonmagnetic garnet wafer must be removed from the grown magnetic thick film by mechanical machining.

It is also known that (BiTb)₃Fe₅O₁₂ single crystals can be produced as Re₃Fe₅O₁₄₂ crystals by baking (Japanese Patent Application Laid-open No. 8-91998 and the like). It is disclosed that these methods allow single crystals that have relatively low insertion loss to be manufactured by first joining a sinter and a single crystal and then heating the joined material and keeping it at about 1300° C. Disclosed as separate baking techniques are those in which ferrite single crystals for magnetic heads are manufactured by laminating together a single crystal and a polycrystal, and heat-treating them within a temperature range in which discontinuous particle growth is prevented (Japanese Patent Application Laid-open Nos. 57-92591, 60-195096, 55-162496, 57-92599, and the like).

However, single crystals obtained by these baking techniques have inadequate quality. Specifically, these conventional products, although single crystals, have high concentrations of grain boundaries with small inclination (subboundaries), dislocations, remaining air pockets, and the like, and there is still room for improvement in terms of quality.

Efficiently providing a single crystal in which these defects are reduced or prevented would make it possible to enhance the performance of products in which such single crystals are used, and to further expand the applications of single crystals.

Consequently, a principal object of the present invention is to efficiently provide a higher-quality rare-earth iron garnet single crystal.

### BRIEF DESCRIPTION OF THE DRAWINGS

FIG. 1 is a schematic depicting the physical relationship between the crystal growth start portion x and end part y during crystal growth;

FIG. 2 is a schematic (cross-sectional view) depicting the state in which a seed crystal portion is heated during crystal growth;

FIG. 3 is a schematic (cross-sectional view) depicting the state in which the end part of a polycrystal is forcibly cooled during crystal growth;

FIG. 4 is an image depicting dislocations in a commercially available single crystal (a) and in the single crystal of the present invention (b);

FIG. 5 is a schematic depicting dislocations A, low-angle tilt boundaries B, and crystal grains C that form the grain boundaries with small inclination as a result of sample etching;

FIG. 6 is a schematic depicting a method for measuring the mean temperature gradient in an embodiment;

FIG. 7 is a schematic depicting (a) the step for producing a seed crystal by irradiation with a CO₂ laser, (b) the state in which the seed crystal is formed, and (c) the step for growing the seed crystal by heating in embodiment 7;

FIG. 8 is a diagram depicting the basic structure of a polarization-dependent optical isolator;

FIG. 9 is a diagram depicting the basic structure of an optical isolator fabricated using the single crystal of the present invention: and

FIG. 10 is a diagram depicting the basic structure of a conventional optical isolator module and an optical isolator module equipped with fiber.

### DISCLOSURE OF THE INVENTION

As a result of extensive research aimed at overcoming the shortcomings of the prior art, the inventors perfected the present invention upon discovering that the aforementioned object can be attained by fabricating a single crystal by a specific process.

Specifically, the present invention relates to the following rare-earth iron garnet single crystal and a manufacturing method thereof.

1. A rare-earth iron garnet single crystal, substantially composed of an Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from Al, Ga, Sc, In, Sn and transition metal elements with atomic numbers of 22 to 30; and 0≦x<5), with the number n per unit surface area (grains/cm²) of crystal grains that form low-angle tilt boundaries equal to 0≦n≧10².

2. A rare-earth iron garnet single crystal, substantially composed of an Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30: and 0≦x<5), with the dislocation density (excluding dislocations that form low-angle tilt boundaries) equal to 1×10⁵ dislocations/cm² or less.

3. The rare-earth iron garnet single crystal according to claim 1 or 2, wherein the pore volume is 200 vol. ppm or less.

4. The rare-earth iron garnet single crystal according to claim 1 or 2, wherein the refractive index distribution in the near-infrared wavelength range with wavelengths of 1.3 to 2.0 μm is 5×10⁻³ to 1×10⁻⁶.

5. The rare-earth iron garnet single crystal according to claim 1 or 2, wherein the purity is 99.5 wt % or greater.

6. A method for producing a rare-earth iron garnet single crystal substantially composed of an Re₃Fe₅₋ₓMₓO₁₂ single crystal by molding an oxide powder whose composition has an Re:Fe₅₋ₓMₓ molar ratio (where Re is at least one element selected from the group consisting of Y, Bi, Ca, and lanthanide rare-earth elements with atomic numbers of 62 to 71: M is at least one element selected from the group consisting of Al, Ga, Sc, In, Sn and transition metal elements with atomic numbers of 22 to 30; and 0≦x<5) of 3.00:4.99 to 5.05, and heat-treating the resulting molding or sinter at 900 to 1500° C. to induce crystal growth,

wherein the molding or sinter is subjected to a mean temperature gradient of 10° C./cm or greater by performing at least one treatment selected from (a) beating the crystal growth start portion and (b) cooling an end part other than this portion during crystal growth.

7. The manufacturing method according to claim 6, wherein the oxide powder is a mixed powder comprising:

1) an Re oxide powder (where Re is at least one element selected from the group consisting of Y, Bi, Ca, and lanthanide rare-earth elements with atomic numbers of 62 to 71); and

2) (1) an iron oxide powder or (2) a powder comprising at least one element selected from the group consisting of Al, Ga, Sc, In, Sn and transition metal elements with atomic numbers of 22 to 30, and an iron oxide powder.

8. The manufacturing method according to claim 7, wherein

1) the primary particle diameter of the Re iron oxide powder (where Re is at least one element selected from the group consisting of Y, Bi, Ca, and lanthanide rare-earth elements with atomic numbers of 62 to 71) is 20 to 500 nm, and the BET specific surface area is 5 to 50 m²/g; and

2) the primary particle diameter of (1) the iron oxide powder or (2) the powder comprising at least one material selected from the group consisting of aluminum oxide powder, gallium oxide powder, scandium oxide powder, indium oxide powder, tin oxide powder and oxide powders of transition metals with atomic numbers of 22 to 30, and an iron oxide powder is 100 to 1000 nm, and the BET specific surface area is 3 to 30 m²/g.

9. A method for manufacturing a rare-earth iron garnet single crystal substantially composed of an Re₃Fe₅₋ₓMₓO₁₂ single crystal by bringing an Re₃M₅O₁₂ or Re₃Fe₅₋ₓMₓO₁₂ single crystal into contact as a seed crystal with an Re₃Fe₅₋ₓMₓO₁₂ sinter whose composition has an Re:Fe₅₋ₓMₓ molar ratio (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) of 3.00:4.99 to 5.05, and then performing a heat treatment at 900 to 1500° C. to induce crystal growth,

wherein the sinter is subjected to a mean temperature gradient of 10° C./cm or greater by performing at least one treatment selected from (a) heating the seed crystal portion and (b) cooling an end part other than this portion during crystal growth.

10. The manufacturing method according to claim 9, wherein the Re₃Fe₅₋ₓMₓO₁₂ sinter (where Re is at least one element selected the group consisting of from Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) has a relative density of 99% or greater.

11. The manufacturing method according to claim 9, wherein the (100), (110), or (111) plane of an Re₃M₅O₁₂ or Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) is polished, and the polished plane is brought into contact with an Re₃Fe₅₋ₓMₓO₁₂ sinter. 12. The manufacturing method according to claim 11, wherein the average surface roughness Ra of the polished plane is 1.0 nm or less, and the flatness λ is 633 nm or less. 13. The manufacturing method according to claim 9, wherein part or all of the Re₃Fe₅₋ₓMₓO₁₂ sinter (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) is polished to an average surface roughness Ra of 1.0 nm or less and a flatness λ of 633 nm or less, and the polished plane is brought into contact with an Re₃M₅O₁₂ or Re₃Fe₅₋ₓMₓO₁₂ single crystal.

14. The manufacturing method according to claim 9, wherein an aqueous solution containing at least one element selected from Re, Fe, and M is applied to at least one contact surface of the Re₃Fe₅₋ₓMₓO₁₂ sinter (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30: and 0≦x<5) and the Re₃M₅O₁₂ or Re₃Fe₅₋ₓMₓO₁₂ single crystal.

15. A method for manufacturing a rare-earth iron garnet single crystal substantially composed of an Re₃Fe₅₋ₓMₓO₁₂ single crystal by performing a heat treatment at 900 to 1500° C. to induce crystal growth after the seed crystal of an Re₃Fe₅₋ₓMₓO₁₂ single crystal is formed by irradiating with a laser beam an Re₃Fe₅₋ₓMₓO₁₂ sinter whose composition has an Re:Fe₅₋ₓMₓ molar ratio (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) of 3.00:4.99 to 5.05, this method for manufacturing a rare-earth iron garnet single crystal wherein the sinter is subjected to a mean temperature gradient of 10° C./cm or greater by performing at least one treatment selected from (a) heating the seed crystal portion and (b) cooling an end part other than this portion during crystal growth.

16. The manufacturing method according to claim 15. wherein the wavelength of the laser beam is 0.2 to 11 μm (excluding the transmission wavelength of the Re₃Fe₅₋MₓO₁₂).

17. The manufacturing method according to claim 15, wherein the irradiation area of the laser beam is 1 mm² or less.

18. The manufacturing method according to claim 15, wherein the Re₃Fe₅₋ₓMₓO₁₂ sinter is irradiated with a laser beam while heated to leas than 1300° C.

19. The manufacturing method according to claim 6, 9, or 15, wherein an oxide capable of forming a liquid phase during crystal growth is allowed to be present in the molding or sinter.

20. The manufacturing method according to claim 6, 9, or 15, wherein the temperature increase rate is kept at 50° C./h or less during crystal growth.

21. The manufacturing method according to claim 6, 9, or 15, wherein the cooling is performed by blowing a coolant onto the end portion.

22. The manufacturing method according to claim 6, 9, or 15, wherein the cooling is performed by pressing a heat sink material comprising a metal or an inorganic material against the end portion, and bringing a coolant into contact with the heat sink material.

23. The manufacturing method according to claim 6, 9, or 15, wherein the growth of the single crystal is controlled by varying (1) the temperature increase rate or (2) both the temperature increase rate and the coolant flow rate.

24. A device in which the rare-earth iron garnet single crystal according to claim 1 or 2 is used.

1. Rare-Earth Iron Garnet Single Crystal

The rare-earth iron garnet single crystal of the first invention has a distinctive feature of substantially composed of an Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5), with the number n per unit surface area (grains/cm²) of crystal grains that form low-angle tilt boundaries equal to 0≦n≦10².

The rare-earth iron garnet single crystal of the second invention has a distinctive feature of substantially composed of an Re₃Fe₅₋ₓMₓO₁₂ single crystal (where Re is at least one element selected from the group consisting of Y, Bi, Ca, and lanthanide rare-earth elements with atomic numbers of 62 to 71: M is at least one element selected from the group consisting of Al, Ga, Sc, In, Sn and transition metal elements with atomic numbers of 22 to 30: and 0≦x<5), with the dislocation density (excluding dislocations that form low-angle tilt boundaries) equal to 1×10⁵ dislocations/cm² or less.

In the description that follows, the single crystal of the first invention is referred to as “the first-invention single crystal,” the single crystal of the second invention is referred to as “the second-invention single crystal,” and the term “the present-invention single crystal” is used to collectively refer to both.

The first-invention single crystal has a distinctive feature whereby the number a per unit surface area (grains/cm²) of crystal grains that form low-angle tilt boundaries (also referred to as “small-angle tilt boundaries” or “sub-grain boundaries”) is 0≦n<10² (preferably 0≦n≦80, and more preferably 0≦n≦50). A single crystal does not have crystal grain boundaries (so-called large-angle tilt grain boundaries), but an individual crystal becomes oriented in a different direction from adjacent crystals in the process of crystal growth, and low-angle tilt boundaries sometimes form as a result (the difference in direction between the grain boundaries is commonly 10° or less). Such low-angle tilt boundaries include two types of boundaries: tilt grain boundaries (boundary surfaces composed of parallelly aligned edge dislocations) and twist grain boundaries (type of boundary in which the directions of two crystals having a joint grain boundary are rotated in relation to each other about the direction perpendicular to the dislocation plane). Specifically, low-angle tilt boundaries are grain boundaries comprising a complex arrangement of edge dislocations and screw dislocations. With low-angle tilt boundaries, the domain portions enclosed in the boundary surfaces thereof are built up during the growth of a single crystal. Specifically, increasing the aforementioned number per unit surface area is equivalent to increasing the number of low-angle tilt boundaries and produces a proportional decrease in the quality of the single crystal. For example, magneto-optics characteristics are adversely affected and other problems encountered when the aforementioned number per unit surface area is excessively high. Consequently, the aforementioned number is defined in the present invention as commonly being 100 grains/cm² or less.

The second-invention single crystal has a distinctive feature whereby the dislocation density of the single crystal is usually 1×10⁵ dislocations/cm² or less (preferably 1×10⁴ dislocations/cm² or less, and more preferably 1×10³ dislocations/cm² or less). Despite being a single crystal, the material still contains dislocations, and raising the dislocation density thereof too high will create quality problems for the single crystal in the same manner as with low-angle tilt boundaries. The lower limit of dislocation density, while not limited in any particular way, may commonly be kept at about 1×10² dislocations/cm² because of considerations related to economic efficiency and the like. A low-angle tilt boundary is a formation in which edge dislocations and screw dislocations have three-dimensional continuity. Specifically, a low-angle tilt boundary is a defect on a grain boundary and a dislocation density is a defect that occurs inside a crystal grain, with the two (low-angle tilt boundary and dislocation density) being distinguished in the present invention.

The single crystal of the present invention preferably satisfies the definition of a low-angle tilt boundary and the definition of a dislocation density. Specifically, it is more preferable to have a rare-earth iron garnet single crystal that substantially comprises an Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5), with the number n per unit surface area (grains cm²) of crystal grains that form low-angle tilt boundaries equal to 0≦n≦10², and the dislocation density (excluding dislocations that form low-angle tilt boundaries) equal to 1×10⁵ dislocations/cm² or less.

The first-invention single crystal and second-invention single crystal have a common composition. Specifically, both substantially comprise an Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5).

Re is at least one element selected from the group consisting of Y, Bi, Ca, and lanthanide rare-earth elements with atomic numbers of 62 to 71. Specific examples of such lanthanide rare-earth elements include Sm, Eu, Gd, Tb, Dy, Ho, Er, Tm, Yb, and Lu. M is at least one element selected from the group consisting of Al, Ga, So, In, Sn and transition metal elements with atomic numbers of 22 to 30. These elements-may be appropriately selected in accordance with the desired characteristics. For example, Bi can be used to increase the Faraday rotation angle. Tb can be used to keep the temperature coefficient of the Faraday rotation angle constant.

In addition, x is 0≦x≦5, and preferably 0≦x≦3. Specifically, some of the Fe sites in the present-invention single crystal may be substituted with M in accordance with the intended application of the single crystal or the like.

The pore volume of the present-invention single crystal is preferably 200 vol. ppm or less, and particularly preferably 20 vol. ppm or less. The lower limit of pore volume, while not subject to limitations, may commonly be kept at about 1 vol. ppm because of considerations related to economic efficiency and the like. Even better optical characteristics or the like can be obtained by keeping the pore volume within this range. For example, an optical isolator transmits (and polarizes at the same time) semiconductor laser light in a wavelength band of 1.3 to 1.5 μm, and can therefore be endowed with excellent characteristics as a result of minimizing insertion loss by keeping the pore volume at 200 vol. ppm or less.

The refractive index distribution of the present-invention single crystal in the near-infrared wavelength region with wavelengths of 1.3 to 2.0 μm is preferably about 5×10⁻³ to 1×10⁻⁵. In particular, this value is preferably kept at a minimum when the present-invention single crystal is used as an optical material.

Although the present-invention single crystal has a composition that substantially comprises the aforementioned Re₃Fe₅₋ₓMₓO₁₂ component, unavoidable impurities may also be contained. The purity of this component preferably is higher, and is commonly 99.5 wt % or greater, and particularly 99.9 wt % or greater.

The size of the single crystal is not limited in any particular way and can commonly be varied in an appropriate manner within a range of 5 mm³ or greater in accordance with the intended application of the product or the like. As is also shown in the embodiments that follow, single crystals measuring, for example, 10 cm³ or greater are also included in the present invention.

2. Manufacturing Method (First Method)

The first method is a method for manufacturing a rare-earth iron garnet single crystal substantially composed of an Re₃Fe₅₋ₓMₓO₁₂ single crystal by molding an oxide powder whose composition has an Re:Fe₅₋ₓMₓ molar ratio (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) of 3.00:4.99 to 5.05, and heat-treating the resulting molding or sinter at 900 to 1500° C. to induce crystal growth, wherein the molding or sinter is subjected to a mean temperature gradient of 10° C./cm or greater by performing at least one treatment selected from (a) heating the crystal growth start portion and (b) cooling an end part other than this portion during crystal growth.

An oxide powder is first prepared. The oxide powder may be a single oxide powder (an Re- and Fe-containing complex oxide or mixed oxide (Re₃Fe₅₋ₓMₓO₁₂ powder or the like)) or a mixed powder comprising two or more types of oxide powder as long as the powder has a composition with an Re:Fe molar ratio of 3.00:4.99 to 5.05 (preferably 3.00:4.995 to 5.020).

In the first method, the oxide powder used is preferably a mixed powder comprising:

1) an Re oxide powder (where Re is at least one element selected from the group consisting of Y, Bi, Ca, and lanthanide rare-earth elements with atomic numbers of 62 to 71); and

2) (1) an iron oxide powder or (2) a powder comprising at least one element selected from the group consisting of Al, Ga, Sc, In, Sn and transition metal elements with atomic numbers of 22 to 30, and an iron oxide powder.

In this case, the powder of 1) above may have a primary particle diameter of 20 to 500 nm, and a BET specific surface area of 5 to 50 m²/g. In addition, the powder of 2) above may have a primary particle diameter of 100 to 1000 nm, and a BET specific surface area of 3 to 30 m²/g.

The primary particle diameter of these powders can be determined by TEM (transmission electron microscopy), SEM (scanning electron microscopy), or the half-width of a diffraction peak in an x-ray diffraction analysis. Specifically, the diameter is a value determined by calculating the mean major axis of arbitrarily selected 100 particles in the case of SEM or TEM.

In the present invention, an oxide capable of forming a liquid phase during crystal growth may further be added in an amount of 0-01 to 1 wt %. It is possible, for example, to use at least one oxide selected from Bi₂O₃ (in which case the total amount of Re is an excess amount of greater than 3.0), PbO, SiO₂, B₂O₃, Li₂O, Na₂O, K₂O, GeO₂, P₂O₅, and the like. This addition causes a low-melting substance to form from the matrix and allows a single crystal to be grown in a state in which a liquid phase is present along the crystal growth boundary surface (boundary surface between the single crystal and polycrystal) during crystal growth. In this case, conversion to a single crystal can be initiated even with crystal growth via a liquid phase (repeated cycles in which the constituent particles of a polycrystal are first melted in a liquid phase and are then reprecipitated on the crystal growth boundary surface of the single crystal) by allowing traces of liquid-phase components to be present along the crystal growth boundary surface. When this method is used, an Re₃Fe₅₋ₓMₓO₁₂ molding or sinter containing the aforementioned specific amounts of oxides can be produced and the first method then applied, although the aforementioned oxides may occasionally be introduced into the grown crystal. For this reason, the oxide content is kept within the aforementioned specific content range.

For the aforementioned oxide powder as such, it is possible to use a commercially available product or a powder obtained by a solid-phase technique in which the oxides of constituent elements are blended together, by a coprecipitation technique in which a homogenized powder is obtained by the chemical pretreatment of the constituent elements, or by a uniform deposition technique, an alkoxide technique, or any other publicly known technique. In particular, the solid-phase technique is preferred because the present-invention single crystal often has a complex composition, and the target composition can in this case be obtained in a reliable manner merely by weighing the individual oxide powders on electronic scales or the like. The purity of these powders, while not subject to limitations, is preferably 99.8 wt % or greater.

When a mixed powder is used, the individual powders may be mixed by a known mixing method. In particular, wet mixing is preferred. Specifically, the preferred way is, for example, to add a solvent (water, alcohol, or the like) and an optional dispersant, binder, or the like to two or more oxide powders, and to mix the ingredients in a wet state using a ball mill or the like. The mixing time, while not limited in any particular way, can commonly be kept at 5 hours or greater. The slurry obtained by wet mixing can be fashioned into a mixed granulated powder by spray drying or another type of drying.

The oxide powder is subsequently formed into a shaped body. Any publicly known forming method, such as single-screw pressing or cold hydrostatic molding, may be used. The density of the shaped body, while not subject to limitations, may be appropriately set in accordance with the intended application of the commercial product or the like.

The shaped body may also be baked as needed in accordance with a known method. It is possible, for example, to obtain a sintered body by baking the shaped body in an oxidizing atmosphere. The baking temperature is kept below the crystal growth temperature for this composition. The sintered body includes a calcined body, a regular sinter, or the like. In particular, a sintered body with a relative density of 95% or greater is preferred.

The shaped body or the sintered body is subsequently heat-treated at the usual temperature of about 900 to 1500° C., or a preferred temperature of 950 to 1500° C., to induce crystal growth. The temperature can be appropriately set in accordance with the composition of the shaped body used or the like. When, for example, Bi is substituted for Re, the temperature is determined by the Bi content. A rare-earth iron garnet single crystal can be obtained by conducting the heat treatment within a range of 1300 to 1500° C. when there is no Bi substitution, and 900 to 1050° C. when the Bi content in Re is about 50% or greater. The heat treatment atmosphere may, for example, be an oxidizing atmosphere, an inert gas atmosphere, the atmosphere, or the like, and may be appropriately selected in accordance with the composition of the single crystal or the like. In addition, the heat treatment time may be appropriately selected in accordance with the heat treatment temperature, the desired size of the single crystal, and the like.

In the first method, the temperature increase rate may be adjusted during crystal growth. Specifically, the rate is preferably 50° C./h or less, and more preferably 20° C./h or less. Efficient crystal growth can be accomplished by adjusting the temperature increase rate.

In the first method, the shaped body or the sintered body is subjected to a mean temperature gradient of 10° C./cm or greater by performing at least one treatment selected from (a) heating the crystal growth start portion and (b) cooling an end part other than the aforementioned portion during crystal growth.

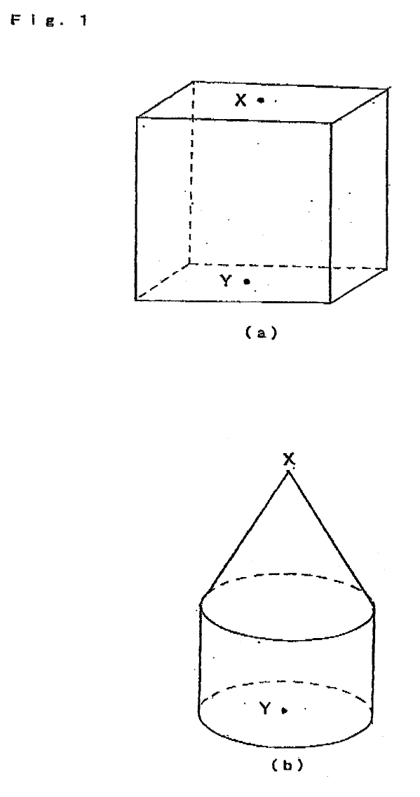

The crystal growth start portion can be defined as an arbitrary portion of the shaped body or the sintered body. The end part, which is the portion that is commonly last to be converted to a single crystal, can be appropriately set in accordance with the shape of the shaped body or the sintered body, the desired crystal growth direction, or the like. The crystal growth start portion and end part may also include the areas around these portions as long as the effect of the present invention is not compromised. In the example of a cubic molding or sinter such as the one shown in FIG. 1(a), setting the central part x on one of the faces thereof (at the intersection of the diagonals across this face) to be the crystal growth start portion will yield the central part y on the face opposite from the first face, or the area around this part as the end part.

In particular, a single crystal can be obtained even more efficiently in accordance with the first method by forming a pointed crystal growth start portion in the same manner as in the Bridgman technique. If, for example, the tip of the shaped body or the sintered body is fashioned into a cone, as shown in FIG. 1(b), the present-invention single crystal can be manufactured with high efficiency by making this portion into the crystal growth start portion because the tip part x is apt to form a single crystal (seed crystal).

The term “mean temperature gradient” in the present invention refers to a value obtained by dividing the temperature difference between the hottest and coolest portions of the molding or sinter by the shortest distance between the hottest and coolest portions. Usually the hottest portion is the crystal growth start portion, and the coolest portion is the end part. The temperature difference can be measured by placing thermocouples on the hottest and coolest portions.

According to the present invention, the molding is subjected to a temperature gradient such that the mean temperature gradient is 10° C./cm or greater, and preferably 50° C./cm or greater. Keeping the mean temperature gradient below 10° C./cm has the risk of creating a large number of grain boundaries with small inclination in the resulting single crystal or producing an excessively high dislocation density. The upper limit of the mean temperature gradient, while not limited in any particular way, may commonly be kept at about 200° C./cm.

The heating method described in (a) above has no limitations as long as the crystal growth start portion can be heated in a concentrated manner. For example, the treatment can be appropriately accomplished by heating with a heater, laser beam, or the like. The heat treatment may also combine heating in an electric furnace or the like.

The cooling method described in (b) above has no limitations as long as the end part can be cooled in a concentrated manner. It is possible, for example, to use a method in which air, oxygen, nitrogen, or another coolant is blown, or a method in which a heat sink material comprising metal or an inorganic material is pressed against, or brought into contact with, the end portion, and air or another coolant is brought into contact with, or blown onto, the heat sink material. The heat sink material may be an MgO sinter or other ceramic, or platinum or another metal. The metal or inorganic material may be a single crystal or a polycrystal. The heat sink material, while not limited in terms of shape, may commonly be fashioned into a plate.

The treatments described in (a) and (b) above may be used together. Specifically, the end part may be cooled while the crystal growth start portion is heated. Combining the two treatments makes it possible to obtain a higher mean temperature gradient.

A coarse single crystal grain can be manufactured by heat-treating the shaped body in this manner, and a single crystal of the desired size can be obtained by allowing the grain to grow. According to the present invention, a single crystal measuring, for example, about 10 to 30 mm or greater on a side can thus be produced.

3. Manufacturing Method (Second Method)

The second method is a method for manufacturing a rare-earth iron garnet single crystal substantially composed of an Re₃Fe₅₋ₓMₓO₁₂ single crystal by bringing an Re₃M₅O₁₂ or Re₃Fe₅₋ₓMₓO₁₂ single crystal into contact as a seed crystal with an Re₃Fe₅₋ₓMₓO₁₂ sintered body whose composition has an Re:Fe₅₋ₓMₓ molar ratio (where Re is at least one element selected from the group consisting of Y, Bi, Ca, and lanthanide rare-earth elements with atomic numbers of 62 to 71: M is at least one element selected from the group consisting of Al, Ga, So, In, Sn and transition metal elements with atomic numbers of 22 to 30: and 0≦x<5) of 3.00:4.99 to 5.05, and then performing a heat treatment at 900 to 1500° C. to induce crystal growth, this method for manufacturing a rare-earth iron garnet single crystal wherein the sinter is subjected to a mean temperature gradient of 10° C./cm or greater by performing at least one treatment selected from (a) heating the seed crystal portion and (b) cooling an end part other than this portion during crystal growth. The second method is preferred over the first method in that a large single crystal with a more defined crystallization direction can be produced more rapidly than in the first method.

The Re₃Fe₅₋ₓMₓO₁₂ sintered body is not limited in any particular way as long as the composition has an Re:Fe₅₋ₓMₓ molar ratio of 3.00:4.99 to 5.05 (preferably 3.00:4.995 to 5.020). In principle, a polycrystal (preferably one with a mean crystal grain size of 20 μm or less) can be used as the sinter. The sinter can be manufactured by a known method. For example, normal-pressure sintering, hot pressing, HIP (hot isostatic pressing), or another method can be employed for sintering. Any of the single crystals present in the polycrystal, which is obtained by subjecting the shaped body obtained by the first method to sintering for an appropriate time at an appropriate temperature, can be used in the second method.

Another feature of the second method is that an oxide capable of forming a liquid phase during crystal growth may be added in advance to the sinter in an amount of 0.01 to 1 wt %. It is possible, for example, to use at least one oxide selected from Bi₂O₃ (in which case the total amount of Re is an excess amount of greater than 3.0), PbO, SiO₂, B₂O₃, Li₂O, Na₂O, K₂O, GeO₂, P₂O₅, and the like. This addition causes a low-melting substance to form from the molding and allows a single crystal to be grown in a state in which a liquid phase is present along the crystal growth boundary surface (boundary surface between the single crystal and polycrystal) during the formation of the single crystal from the seed crystal in the sinter direction. In this case, conversion to a single crystal can be initiated even with crystal growth via the liquid phase (that is, repeated cycles in which the constituent particles of the polycrystal are first melted in the liquid phase and are then reprecipitated on the crystal growth boundary surface of the single crystal) by allowing traces of liquid-phase components to be present along the crystal growth boundary surface. When this method is used, an Re₃Fe₅₋ₓMₓO₁₂ sinter containing the aforementioned specific amounts of oxides may be produced and the first method then applied, although the aforementioned oxides may occasionally be introduced into the grown crystal. For this reason, the oxide content is kept within the aforementioned specific content range.

In the second method, the relative density of the Re₃Fe₅₋ₓMₓO₁₂ sinter, while not subject to limitations, is commonly 99% or greater, and is particularly preferably 99.8% or greater. A single crystal of even higher quality can thus be obtained. The size of the Re₃Fe₅₋ₓMₓO₁₂ sintered body can be varied depending on the desired size of the single crystal or the like, but can commonly be equal to or greater than the volume of the subsequent single crystal. The relative density can be controlled by the density of the shaped body, the sintering time and temperature, and the like.

The Re₃M₅O₁₂ or Re₃Fe₅₋ₓMₓO₁₂ single crystal (where Re is at least one element selected from the group consisting of Y, Bi, Ca, and lanthanide rare-earth elements with atomic numbers of 62 to 71: M is at least one element selected from the group consisting of Al, Ga, Sc, In, Sn and transition metal elements with atomic numbers of 22 to 30; and 0≦x<5) used as the seed crystal may be a single crystal obtained by the first or second method, or it may be a single crystal obtained by an FZ technique, flux technique, TSSG technique, or other publicly known single crystal production technique. The size (volume) of the single crystal used, while not limited in any particular way, can commonly be about 1 mm³ or greater.

The single crystal may have the same composition as the sinter, or mutually different compositions may be involved.

The method for bringing the sinter and single crystal into contact with each other, while not limited in any particular way, may preferably involve bringing the two into contact with each other without any gaps. In this case, a heat treatment is performed while the sinter and the single crystal are kept in contact with each other under pressure. The pressure applied during contact may be appropriately varied depending on the type of sinter/single crystal, contact surface area, and the like. For example, the pressure can be kept at about 9.8 MPa or less when an YIG single crystal and YIG sinter are used.

Another feature of the second method is that when the sinter and the single crystal are brought into contact with each other, the surface (contact plane) of at least one of them may be polished. In the aforementioned single crystal, the (100), (110), or (111) plane thereof may be polished. In this case, the polished plane is preferably polished such that the average surface roughness Ra is 1.0 nm or less, and the flatness λ is 633 nm or less. In the sinter, at least the plane in contact with the single crystal is preferably polished such that the average surface roughness Ra is 1.0 nm or less, and the flatness λ is 633 nm or less.

A heat treatment is subsequently carried out at 900 to 1500° C. (preferably 950 to 1500° C.) to induce crystal growth. The heat treatment temperature can be appropriately set in accordance with the composition of the sinter or seed crystal or the like. The crystal growth can be performed by conducting the heat treatment within a range of 1300 to 1500° C. when there is no substitution of Re by Bi, and 900 to 1050° C. when the Bi content in Re is about 50%. The heat treatment atmosphere, while not limited in any particular way, can be the same as in the first method. The heat treatment time may be appropriately set in accordance with the heat treatment temperature, the desired size of the single crystal, or the like.

In the second method, the temperature increase rate may be adjusted during crystal growth. Specifically, the rate may be 50° C./h or less, and preferably 20° C./h or less. Efficient crystal growth can be accomplished by adjusting the temperature increase rate.

In the second method, the sintered body is subjected to a mean temperature gradient of 10° C./cm or greater by performing at least one treatment selected from (a) heating the seed crystal portion and (b) cooling an end part other than the aforementioned portion during crystal growth.

The seed crystal portion includes, in addition to the seed crystal as such, the contact portion between the seed crystal and the sintered body. This portion can be partially heated using a heater, laser beam, or the like. The end part, which is the portion that is commonly last to be converted to a single crystal, can be appropriately set in accordance with the shape of the sinter, the desired crystal growth direction, or the like. The seed crystal portion and end part may also include the areas around these portions as long as the effect of the present invention is not compromised. In the example of a cubic or cylindrical sinter, placing the seed crystal in the central portion on one of the faces thereof (at the intersection of the diagonal lines or in the center of the circle) will yield the face opposite from the first face, or the central portion thereof as the end part.

The term “mean temperature gradient” in the present invention refers to a value obtained by dividing the temperature difference between the hottest and coolest portions of sinter by the shortest distance between the hottest and coolest portions. Usually the hottest portion is the crystal growth start portion, and the coolest portion is the end part. The temperature difference can be measured by placing a thermocouple on the hottest and coolest portions.

According to the present invention, the sinter is subjected to a temperature gradient such that the mean temperature gradient is 10° C./cm or greater, and preferably 50° C./cm or greater. Keeping the mean temperature gradient below 10° C./cm has the risk of creating a large number of low-angle tilt boundaries in the resulting single crystal or producing an excessively high dislocation density. The upper limit of the mean temperature gradient, while not limited in any particular way, may commonly be kept at about 200° C./cm.

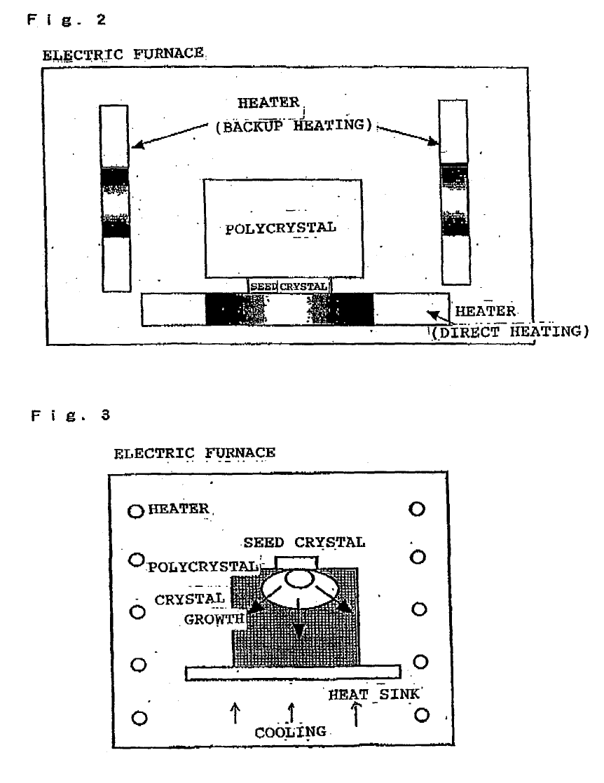

The heating method described in (a) above has no limitations as long as the seed crystal portion can be heated in a concentrated manner. For example, the treatment can be appropriately accomplished by heating with a heater, laser beam, or the like. Such a heat treatment may also combine heating in an electric furnace or the like. FIG. 2 depicts an aspect (cross-sectional view) in which a seed crystal is directly heated with a heater. The heater is installed in a state of direct contact with the seed crystal, and the seed crystal is heated by this heater. The heated seed crystal grows as a crystal toward the sinter (polycrystal). Auxiliary heaters (electric furnaces) may also be disposed on both sides of the sinter if necessary.

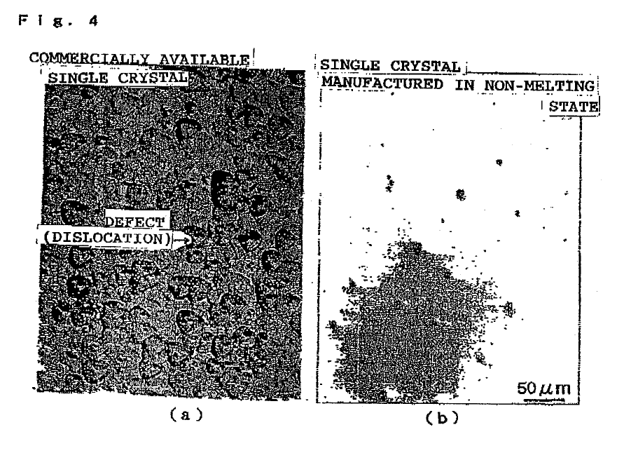

The cooling method described in (b) above has no limitations as long as the end part can be cooled in a concentrated manner. It is possible, for example, to use a method in which air, oxygen, nitrogen, or another coolant is blown, or a method in which a heat sink material comprising metal or an inorganic material is pressed against, or brought into contact with, the end portion, and air or another coolant is blown onto the heat sink material. A material with a thermal conductivity of 5 W/mk or greater, and particularly 10 W/mk or greater, is preferably used as the heat sink material. For example, an MgO sinter or other ceramic, or platinum or another metal can be used as such a material. Such materials may be single crystals or polycrystals. The heat sink material, while not limited in terms of shape, may commonly be fashioned into a plate. FIG. 3 shows an aspect (cross-sectional view) in which a heat sink material is pressed against the end portion, and a gas medium is blown onto the heat sink material for cooling. The sinter (polycrystal) in FIG. 3 is cubic or cylindrical in shape, and when the seed crystal is placed in the central part on one of the faces thereof and crystal growth is initiated, the heat sink material (tabular material) is pressed against the entire face opposite from this face, gas is fed from underneath the heat sink material, and contact is achieved with the heat sink material. The heat sink material and polycrystal as such are cooled, and an unsteady temperature distribution (curved temperature distribution; that is, abrupt temperature variations across the crystal growth boundary surface) can be established in the material, by blowing a gas whose temperature is no greater than the temperature inside the furnace from underneath the heat sink material. This makes it possible to minimize the grain growth of the polycrystal below the crystal growth boundary surface. In addition, the starting temperature of crystal growth can be caused to gradually move downward by keeping constant the cooling conditions from the lower edge and raising the temperature inside the furnace at a constant rate, so that the crystal can be grown at a constant rate and in a single direction. Not only is this approach useful for growing crystals in an unmelted state, but it also allows light scattering (specifically, insertion loss during irradiation from a semiconductor laser) in a material to be reduced, and is linked to higher quality because the pores remaining in the polycrystal not yet converted to a single crystal can be smoothly discharged from the system (from the single crystal) by the use of crystal boundary surface movement.

The treatments described (a) and (b) above may be used together. Specifically, the end part may be cooled while the seed crystal portion is heated. Combining the two treatments makes it possible to obtain a higher mean temperature gradient.

According to another means, the crystal growth boundary surface can be moved and a high-quality single crystal obtained in the same manner by setting the temperature inside the furnace to a level not less than the start temperature of crystal growth, cooling the system while feeding a gas such that the bond between the single crystal and the polycrystal is kept at a temperature approximately equal to the start temperature of crystal growth, and reducing the extent of cooling to match the intensity of crystal growth.

All or part of the portion in contact with the seed crystal and the sintered body is irradiated with a laser beam when the seed crystal portion is irradiated with the laser beam. The energy density of the laser beam (laser light) varies with the beam spot diameter and the like, and may commonly be kept at 10⁷ W/cM² or less. The wavelength may commonly be kept at about 0.2 to 11 μm (excluding the transmission wavelength of the Re₃Fe₅₋ₓMₓO₁₂). The laser generator as such may be a known or commercially available apparatus. The type of laser beam is not subject to limitations and may, for example, be a CO₂ laser beam or an Nd:YAG secondary harmonic generation (SHG) laser beam. Another preferred option is, for example, to place an Re₃Fe₅₋ₓMₓO₁₂ sintered body, which has been brought into contact with an Re₃Fe₅₋ₓMₓO₁₂ single crystal as a seed crystal, in a heating furnace and then to irradiate the sintered body with a laser beam while a heat treatment is carried out.

Another feature of the second method is that an aqueous solution containing at least one element selected from the group consisting of Re, Fe, and M may be applied as needed to at least one contact surface of the sintered body and the single crystal. An aqueous solution of water-soluble salts (organic acid salts, inorganic acid salts, or the like) containing at least one element selected from the group consisting of Re, Fe, and M may be used as such an aqueous solution. Examples include aqueous solutions of YCl₃, Y(NO₃)₃, Fe(NO₃)₃, and FeSO₄, or the like. In this case, the Re and M in the aqueous solution are preferably the same Re and M as those contained in the sintered body. Using the aforementioned aqueous solution makes it possible to improve the adhesion between the single crystal and the sintered body and to manufacture a good-quality single crystal in a more reliable manner. The concentration of the aqueous solution, while not limited in any particular way, may commonly be kept at about 0.5 to 10 wt %.

4 Manufacturing Method (Third Method)

The third method is a method for manufacturing a rare-earth iron garnet single crystal substantially composed of an Re₃Fe₅₋ₓMₓO₁₂ single crystal by performing a heat treatment at 900 to 1500° C. to induce crystal growth after the seed crystal of an Re₃Fe₅₋ₓMₓO₁₂ single crystal is formed by irradiating with a laser beam an Re₃Fe₅₋ₓMₓO₁₂ sintered body whose composition has an Re:Fe₅₋ₓMₓ molar ratio (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) of 3.00:4.99 to 5.05, wherein the sintered body is subjected to a mean temperature gradient of 10° C./cm or greater by performing at least one treatment selected from (a) heating the seed crystal portion and (b) cooling an end part other than this portion during crystal growth. The third method is preferred over the first method in that a large single crystal can be manufactured more rapidly than in the first method.

The Re₃Fe₅₋ₓMₓO₁₂ sintered body is not limited in any particular way as long as the composition has an Re:Fe₅₋Mₓ molar ratio of 3.00:4.99 to 5.05 (where Re is at least one element selected from the group consisting of Y, Bi, Ca, and lanthanide rare-earth elements with atomic numbers of 62 to 71; M is-at least one element selected from the group consisting of Al, Ga, Sc, In, Sn and transition metal elements with atomic numbers of 22 to 30; and 0≦x<5). In principle, a polycrystal (preferably one with a mean crystal grain size of 20 μm or less) can be used as the sintered body. Consequently, a single crystal of a polycrystal, which is obtained by subjecting the shaped body obtained by the first method to sintering for an appropriate time at an appropriate temperature, can be used in the third method.

Another feature of the third method is that an oxide capable of forming a liquid phase during crystal growth may be added in advance to the sintered body in an amount of 0.01 to 1 wt %. It is possible, for example, to use at least one compound selected from Bi₂O₃ (in which case the total amount of Re is an excess amount of greater than 3.0), PbO, SiO₂, B₂O₃, Li₂O, Na₂O, K₂O, GeO₂, P₂O₅, and the like. This addition causes a low-melting substance to form from the matrix and allows a single crystal to be grown in a state in which a liquid phase is present along the crystal growth boundary surface (boundary surface between the single crystal and polycrystal) during the formation of the single crystal from the seed crystal in the sinter direction. In this case, conversion to a single crystal can be initiated even with crystal growth via the liquid phase (that is, repeated cycles in which the constituent particles of the polycrystal are first melted in the liquid phase and are then reprecipitated on the crystal growth boundary surface of the single crystal) by allowing traces of liquid-phase components to be present along the crystal growth boundary surface. When this method is used, an Re₃Fe₅₋ₓMₓO₁₂ sintered body containing the aforementioned specific amounts of oxides can be produced and the first method then applied, although the aforementioned oxides may occasionally be introduced into the grown crystal. For this reason, the oxide content is kept within the aforementioned specific content range.

In the third method, the relative density of the Re₃Fe₅₋ₓMₓO₁₂ sinter is commonly 99% or greater, and is particularly preferably 99.8% or greater. A single crystal of even higher quality can thus be obtained. The relative density can be controlled by the density of the shaped body, the sintering time and temperature, and the like.

In the third method, a seed crystal of an Re₃Fe₅₋MₓO₁₂ single crystal can be formed by irradiation with a laser beam. Specifically, abnormal grain growth (in particular, grain growth to about ten or more times the size of a non-irradiated portion) can be initiated in the irradiated portion. Consequently, the irradiation conditions are not limited in any particular way as long as this type of abnormal grain growth occurs. The energy density of the laser beam (laser light) may be kept at 10⁷ W/cm² or less. The wavelength may commonly be kept at about 0.2 to 11 μm (excluding the transmission wavelength of the Re₃Fe₅₋ₓMₓO₁₂). The laser generator as such may be a known or commercially available apparatus. The type of laser beam is not subject to limitations and may, for example, be a CO₂ laser beam or an Nd:YAG secondary harmonic generation (SHG) laser beam. The irradiation area irradiated by the laser beam, while not subject to limitations, is preferably 1 mm² or less under usual conditions.

The sintered body can be irradiated with the laser beam while being heated as needed. The heating temperature, while not subject to limitations, is less than the temperature at which a crystal grows from a single crystal toward a polycrystal, and this temperature varies greatly with the material composition. For example, the temperature is commonly less than 1400° C., and preferably 800 to 1350° C., when a pure YIG single crystal is grown; and can be less than 1050° C., and preferably 600 to 900° C. when 40 mol % of Bi is substituted for Re. The heating may, for example, be conducted using a heating furnace or the like.

A heat treatment is subsequently conducted at 900 to 1500° C. (preferably 950 to 1500° C.) to induce crystal growth. These methods can be performed in the same manner as the second method. For example, appropriate settings can be selected in accordance with the composition of the sintered body and the like. For example, the crystal growth may be performed within a range of and 900 to 1050° C. when Bi is substituted for Re and the Bi content in Re is about 50% or greater, and at 1300 to 1500° C. when there is no Bi substitution at all. The heat treatment atmosphere, while not limited in any particular way, can be the same as in the first method. The heat treatment time can be appropriately set in accordance with the heat treatment temperature, the desired size of the single crystal, or the like.

In the third method, the temperature increase rate may be adjusted during crystal growth. Specifically, the rate may be 50° C./h or less, and preferably 20° C./h or less. Efficient crystal growth can be accomplished by adjusting the temperature increase rate.

In the third method, the sintered body is subjected to a mean temperature gradient of 10° C./cm or greater by performing at least one treatment selected from (a) heating the seed crystal portion and (b) cooling an end part other than the aforementioned portion during crystal growth.

The seed crystal portion includes, in addition to the seed crystal as such, the contact portion between the seed crystal and the sintered body. This portion can be partially heated using a heater, laser beam, or the like. The end part, which is the portion that is commonly last to be converted to a single crystal, can be appropriately set in accordance with the shape of the sintered body, the desired crystal growth direction, or the like. In the example of a cubic or cylindrical sintered body, placing the seed crystal in the central portion on one of the faces thereof (at the intersection of the diagonal lines or in the center) will yield the central portion of the face opposite from the first face as the end part.

The term “mean temperature gradient” in the present invention has the same meaning as in the second method above. According to the present invention, the sintered body is subjected to a temperature gradient such that the mean temperature gradient is 10° C./cm or greater, and preferably 50° C./cm or greater. Keeping the mean temperature gradient below 10° C./cm has the risk of creating a large number of grain boundaries with small inclination in the resulting single crystal or producing an excessively high dislocation density. The upper limit of the mean temperature gradient, while not limited in any particular way, may commonly be kept at about 200° C./cm.

The heating method described in (a) above and the cooling method described in (b) above can be performed in the same manner as in the above-described second method. In addition, the treatments described in (a) and (b) above may be used together. Specifically, the end part may be cooled while the seed crystal portion is heated. Combining the two treatments makes it possible to obtain a higher mean temperature gradient.

When the seed crystal is irradiated with a laser beam, the energy density of the laser beam (laser light) varies with the beam spot diameter and the like, and may commonly be kept at 10⁷ W/cm² or less. The wavelength may commonly be kept at about 0.2 to 11 μm (excluding the transmission wavelength of the Re₃Fe₅₋ₓMₓO₁₂). The laser beam apparatus as such may be a publicly known or commercially available apparatus. The type of laser beam is not subject to limitations and may, for example, be a CO₂ laser beam or an Nd:YAG second harmonic generated (SHG) laser beam.

When irradiation with a laser beam is used together with heating, the preferred option is, for example, to place an Re₃Fe₅₋ₓMₓO₁₂ sintered body, in which the seed crystal has produced an Re₃Fe₅₋ₓMₓO₁₂ single crystal, in a heating furnace and then to irradiate the seed crystal with a laser beam while this material is heat-treated.

When a single crystal whose composition comprises two or more components is manufactured by a melting and solidification technique, the effect of gravity usually limits the extent to which the uniformity of the composition can be improved. Re₃Fe₅₋ₓMₓO₁₂ single crystals are no exception, and their uniformity presents a problem. Refractive index nonuniformity (that is, compositional nonuniformity) is an issue that has been brought up in connection with the LiTaO₃ single crystals, LiNbO₃ single crystals, and other crystals used in SAW (surface acoustic wave) filters for mobile communication, and research to synthesize some of these single crystals in the weightless space environment has recently been started. Making the internal composition of these materials more uniform is a common issue also encountered when performing the melting and solidification technique, but no solution to this problem has so far been found.

The present invention represents a breakthrough in terms of understanding the ceramic processes related to this problem. In a ceramic process, a starting material is essentially sintered in an unmelted state without being melted, and the constituent elements are constantly in a state in which these elements are confined within a solid (crystal). Specifically, the constituent elements in a solid remain virtually unaffected by gravity, and must therefore be substantially free from the problems of nonuniformity and segregation commonly encountered during single crystal manufacture. A ceramic process produces inferior uniformity in comparison with a single crystal manufactured by the melting and solidification technique because constituent components can travel only over short distances during sintering if the composition distribution of the starting materials in a green compact is nonuniform. For this reason, it is as yet difficult to achieve compositional uniformity in manufacturing processes when ceramic techniques (baking techniques) are involved, and nonuniform results are therefore obtained in comparison with single crystals manufactured by the melting and solidification technique even when the conversion to a single crystal is accomplished by a baking technique.

By contrast, the present invention succeeds in overcoming the shortcomings of the conventional baking techniques, particularly by adopting specific sintering methods and using starting materials-of specific particle size to make it possible to provide single crystals of a greater quality than before on a commercial scale.

Rare-earth iron garnet single crystals of higher quality than that of conventional single crystals can be efficiently obtained by the method for manufacturing a rare-earth iron garnet single crystal in accordance with the present invention. Specifically, it is possible to efficiently produce a single crystal with comparatively few low-angle tilt boundaries, or a single crystal with a comparatively low dislocation density.

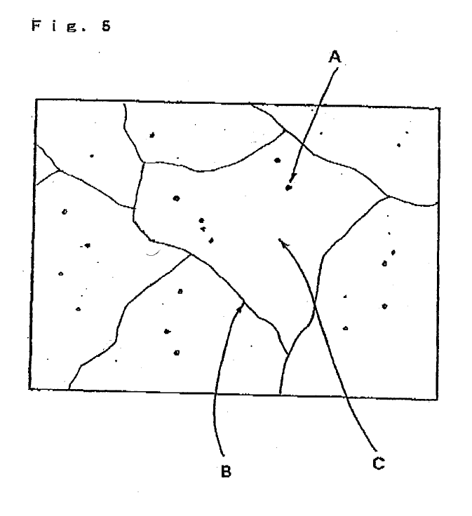

Consequently, a large high-quality single crystal can be provided, for example. As can be seen, for example, in FIG. 4, the currently commercially available single crystal (a) has a large number of dislocations (irregular appearance), whereas the present-invention single crystal (b) has virtually no dislocations. In other words, the present-invention single crystal has a very low dislocation density in comparison with a conventional product despite being the same single crystal.

Thus, high-quality single crystals can be efficiently provided by means of the present-invention single crystal and a manufacturing method thereof, and therefore allow production to be accomplished on a commercial scale. In addition, large single crystals can be produced relatively rapidly, thereby allowing single crystals to be produced on a mass scale and at a low cost. As a result, expansion into other potential applications can be expected.

The present-invention single crystal is expected to be applied in a wide variety of technological fields in addition to applications involving conventional rare-earth iron garnet single crystals, such as isolators for optical communication, magnetic materials for microwaves, high-frequency magnetic filters, and magnetic sensors.

### BEST MODE FOR CARRYING OUT THE INVENTION

Embodiments and comparative examples will now be shown to further elucidate the distinctive features of the present invention. It may be noted, however, that the scope of the present invention is not limited by the scope of the embodiments.

In embodiments 1 to 10, an MgO sinter (thermal conductivity at room temperature: 35 W/mk) with a purity of 99.8 wt % was used as the heat sink material, a sinter was placed on the heat sink material in the manner shown in FIG. 3, air was blown from underneath the heat sink material, and a crystal was grown under cooling. The temperature of the air coolant was set below that of the atmosphere inside the furnace. In embodiment 11, the crystal was grown under direct cooling by air without the use of a heat sink. In this case as well, the mean temperature gradient was 60° C./cm because the temperature difference between the air and the atmosphere inside the furnace was 150° C., and the sample length was 25 mm.

The following methods were used to calculate the number, per unit surface area, of crystal grains that form low-angle tilt boundaries and to measure the dislocation density and refractive index distribution in the embodiments and comparative examples.

(1) Number, Per Unit Surface Area of Crystal Grains That Form Low-angle Tilt Boundaries, and Dislocation Density

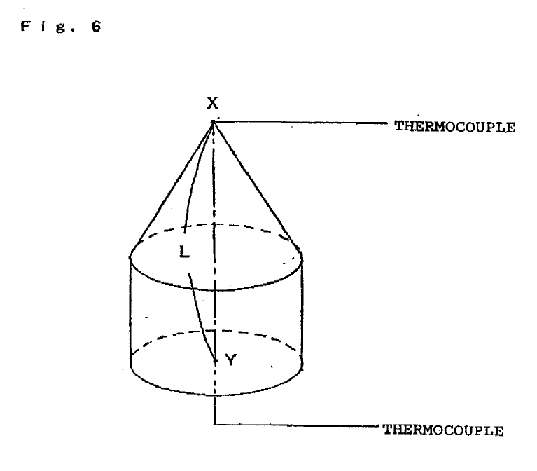

Images of corrosion pits were formed on a sample surface by etching the sample in a hot phosphoric acid solution (stock solution) with a temperature of about 100° C. Images of corrosion pits such as those shown in FIG. 5 were obtained in the presence of low-angle tilt boundaries or dislocations. In FIG. 5, the punctiform images of corrosion pits (A) are dislocations. In FIG. 5, the linear images of corrosion pits are low-angle tilt boundaries (B).

In the present invention, the number of punctiform images of corrosion pits is defined as “dislocation density (dislocations/cm²).” A crystal grain (C) that forms such low-angle tilt boundaries in FIG. 5 is counted as a single grain, and the number of such portions divided by the surface area of observation (cm²) Is defined as “the number per unit of surface area of crystal grains that form low-angle tilt boundaries (grains/cm²).”

(2) Refractive Index Distribution

Measured using the Twyman interferometer. An YAG laser with a wavelength λ₁ of 1.3 μm was used for the light source. A sensing Image obtained from the interferometer was sensed by an InSb detector, and the refractive index distribution within the sample plane was determined based on the resulting interference fringes. The sample was precision-machined to an average surface roughness (Ra) of 0.3 nm or less, a flatness λ₂/10 of (λ₂=633 nm) or less, and a parallelism of within 3 seconds.

(3) Pore Volume

One face of a sample was specularly polished, the surface area of the pores exposed on the surface was summarized at a magnification of 100 to 500 under a reflecting microscope, and the ratio of this surface area to the measurement surface area was calculated as pore volume. In this case, the resulting value was an area ratio, but this value could be easily converted to the pore volume. The surface area of measurement was set to at least 1 cm².

(4) Mean Temperature Gradient

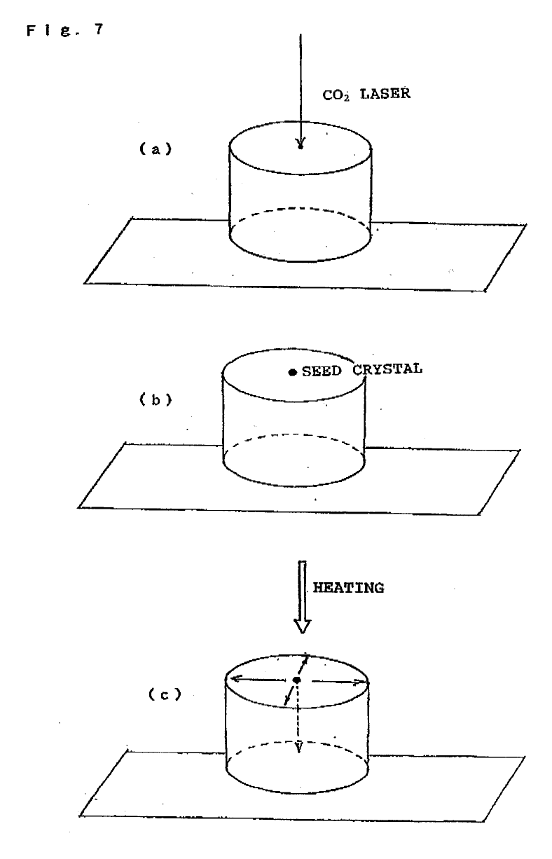

Thermocouples were placed in advance on the crystal growth start portion or seed crystal portion (a) and the end part (b), and the temperature difference ΔT(° C.) was measured, as shown in FIG. 6. The value (ΔT/L) obtained by dividing AT by sample length L (cm) was defined as the mean temperature gradient (° C./cm). In embodiment 1, for example, the mean temperature gradient was 60° C./cm because ΔT was 150° C. and the sample length 2.5 cm.

Embodiment 1

α-Fe₂O₃ powder (mean particle diameter: 0.8 μm) and Y₂O₃ powder (mean particle diameter: 0.1 μm) were used as starting materials, the composition was adjusted to Y:Fe=3.00:5.01 (molar ratio), the two components were wet-mixed in a ball mill, and the resulting mixed powder was CIP-molded (into a disk shape with a diameter of 16 mm and a thickness of 10 mm) at a pressure of 98 MPa. The pressed body was subsequently baked for 10 hours in an oxygen atmosphere at 1330° C. The resulting sintered body comprised coarse YIG (Y₃Fe₅O₁₂) grains of about 8 mm, and a coarse grain for a seed crystal was extracted from this sintered body. The extracted crystal was cut along the (111) plane, and this plane was specularly finished to an average surface roughness Ra of 0.2 nm and a flatness of λ/4. Polycrystalline YIG (diameter: 30 mm, thickness: 25 mm) with a relative density of 99.5% was also obtained by forming a starting material with the same composition as above into the aforementioned disk shape and subjecting the disk to hot press sintering (pressure: 9.8 MPa) for 3 hours in the atmosphere at 1250° C. The end face of the polycrystal was specularly finished to an average surface roughness Ra of 0.2 nm and a flatness of λ₂/4 in the same manner as above, the two polished surfaces of the seed crystal and polycrystal were washed with acetone, and the polished surfaces of the two were superposed onto each other. The materials were kept for 20 hours in an oxygen atmosphere at an average temperature of 1370° C. (since the temperature was raised from 1350 to 1390° C. over a period of 20 hours, the temperature increase rate was 2° C./h) while this state was maintained, and a single crystal was grown under non-melting conditions. The mean temperature gradient during crystal growth was kept at 60° C./cm. After the growth procedure, the polycrystal had become a single crystal to a depth of about 24 mm from the surface bonded to the single crystal. Based on these results, it was concluded that the growth rate was 1.2 mm/h and that growth could be performed at a much higher rate than the growth rate of the conventional melting and solidification technique. The resulting YIG single crystal did not have any low-angle tilt boundaries and had a dislocation density of 1×10² dislocations/cm², a refractive index distribution of 5×10⁻⁴, and a pore volume of 30 vol. ppm.

Embodiment 2

α-Fe₂O₃ powder (mean particle diameter: 0.8 μm), Tb₂O₃ powder (mean particle diameter: 0.3 am), and Bi₂O₃ powder (mean particle diameter: 0.3 μm) were used as starting materials, the composition was adjusted to (Tb+Bi):Fe=3.00:5.01 (molar ratio), the two components were wet-mixed in a ball mill, and the resulting mixed powder was CIP-molded (into a disk shape with a diameter of 16 mm and a thickness of 20 mm) at a pressure of 98 MPa. The shaped body was subsequently baked for 12 hours in an oxygen atmosphere at 1230° C. The resulting sintered body comprised coarse (BiTb)₃Fe₅O₁₂ grains (composition: Bi_{0.5}Tb_{2.5}Fe₅O₁₂) of about 9 mm, and a coarse grain for a seed crystal was extracted from this sinter. The extracted crystal was cut along the (111) plane, and this plane was specularly finished to an average surface roughness Ra of 0.2 nm and a flatness of λ₂/6. Polycrystalline (BiTb)3Fe₄O₁₂ (diameter: 20 mm, thickness: 15 mm) with a relative density of 99.9% was also obtained by forming a starting material with the same composition as above into the aforementioned disk shape and subjecting the disk to hot press sintering (pressure: 19.6 MPa) for 3 hours in an oxygen atmosphere at 1210° C. The end face of the polycrystal was specularly finished to an average surface roughness Ra of 0.2 nm and a flatness of λ₂/4 in the same manner as above, the two polished surfaces of the seed crystal and polycrystal were washed with acetone, and the polished surfaces of the two were superposed onto each other. The materials were kept for 22 hours in an oxygen atmosphere at an average temperature of 1290° C. (since the temperature was raised from 1260 to 1320° C. over a period of 22 hours, the temperature increase rate was 2.7° C./h) while this state was maintained, and a single crystal was grown under non-melting conditions. The mean temperature gradient during crystal growth was kept at 100° C./cm. After the growth procedure, the polycrystal had become a single crystal to a depth of about 15 mm from the surface bonded to the single crystal. Based on these results, it was concluded that the growth rate was 0.7 mm/h and that growth could be performed at a much higher rate than the growth rate of the conventional melting and solidification technique. The resulting (BiTb)₃Fe₅O₁₂ single crystal did not have any low-angle tilt boundaries and had a dislocation density of 5×10² dislocations/cm², a refractive index distribution of 3×10⁻⁵, and a pore volume of 3 vol. ppm.

Embodiment 3

α-Fe₂O₃ powder (mean particle diameter: 0.5 μm) and Y₂O₃ powder (mean particle diameter: 0.05 μm) were used as starting materials, the composition was adjusted to Y:Fe=3.00:5.01 (molar ratio), the two components were wet-mixed in a ball mill, and the resulting mixed powder was CIP-molded (into a disk shape with a diameter of 16 mm and a thickness of 10 mm) at a pressure of 98 MPa. The molding was subsequently baked for 6 hours in an oxygen atmosphere at 1390° C. The resulting sintered body comprised coarse YIG (Y₃Fe₅O₁₂) grains of about 8 mm, and a coarse grain for a seed crystal was extracted from this sintered body. The extracted crystal was cut along the (110) plane, and this plane was specularly finished to an average surface roughness Ra of 0.2 nm and a flatness of λ/4. Polycrystalline YIG (diameter: 30 mm, thickness: 25 mm) with a relative density of 99.8% was also obtained by molding a starting material with the same composition as above into the aforementioned disk shape and subjecting the disk to hot press sintering (pressure: 9.8 MPa) for 3 hours in an oxygen atmosphere at 1220° C. The end face of the polycrystal was specularly finished to an average surface roughness Ra of 0.2 nm and a flatness of λ₂/4 in the same manner as above, the two polished surfaces of the seed crystal and polycrystal were washed with acetone, and the polished surfaces of the two were superposed onto each other. In this case, an aqueous solution in which Fe(NO₃)₃ and Y(NO₃)₃ were adjusted to a molar ratio of 5.00:3.00 was applied to the contacting surfaces of the two. The materials were kept for 18 hours in an oxygen atmosphere at 1460° C. while this state was maintained, and a single crystal was grown under non-melting conditions. The mean temperature gradient during crystal growth was kept at 50° C./cm. After the growth procedure, the polycrystal had become a single crystal to a depth of about 23 mm from the surface bonded to the single crystal. Based on these results, it was concluded that the growth rate was 1.3 mm/h and that growth could be performed at a much higher rate than the growth rate of the conventional melting and solidification technique. The resulting YIG single crystal did not have any low-angle tilt boundaries and had a dislocation density of 1×10² dislocations/cm², a refractive index distribution of 2×10⁻⁶, and a pore volume of 0.1 vol. ppm.

Embodiment 4

Single crystals were grown in the same manner as in embodiment 1.

In the present embodiment, an electric furnace with a molybdenum suicide heating element having an effective capacity of 200 mm×200 mm×200 mm was used, 20 samples were introduced therein, and crystals were grown in a 100% oxygen atmosphere. In the process, efficient crystal growth was conducted by keeping the atmosphere inside the furnace at 1300° C., varying the blow rate of the cooling oxygen gas from 6 L/min to the ultimate value of 0.1 L/min, and continuously moving the start temperature of crystal growth inside the material from the side of the seed crystal to the opposite side at the same time as the material was forcibly cooled. The mean temperature gradient during crystal growth was kept at 50° C./cm.

Each of the treated samples had become a single crystal to a depth of about 24 mm from the surface bonded to the single crystal. The production rate of the single crystals was 338 cm³ per furnace because 20 single crystals (capacity; 16.9 cm³) with a diameter of 30 mm and a length of 24 mm were manufactured. It was learned that high productivity was achieved because the time needed for the growth was 20 hours, yielding 16.9 cm³ as the production volume per unit of time.

Embodiment 5

Single crystals were grown in the same manner as in embodiment 2.

In the present embodiment, the starting material used was obtained by adjusting the composition to (Tb+Bi):Fe=3.00:5.04 and mixing the components in a wet state. Sinters measuring 75 mm in diameter and 50 mm in length were fabricated, three samples were introduced into an electric furnace in which a molybdenum suicide heating element having an effective capacity of 200 mm×200 mm×200 mm was used, and crystals were grown in a 100% oxygen atmosphere. In the process, efficient crystal growth was conducted by keeping the atmosphere inside the furnace at 1420° C., varying the blow rate of the cooling oxygen gas from 5 L/min to the ultimate value of 0.3 L/min, and continuously moving the start temperature of crystal growth inside the material from the side of the seed crystal to the opposite side at the same time as the material was forcibly cooled. The mean temperature gradient during crystal growth was kept at 20° C./cm.

Each of the treated samples had become a single crystal to a depth of about 40 mm from the surface bonded to the single crystal. The production rate of the single crystals was 531 cm³ per furnace because three single crystals (capacity: 177 cm³) with a diameter of 75 mm and a length of 40 mm were obtained. It was learned that high productivity was achieved because the time needed for the growth was 50 hours, yielding 10.6 cm³ of the product per unit of time.

Embodiment 6

α-Fe₂O₃ powder (mean particle diameter; 0.8 μm) and Y₂O₃ powder (mean particle diameter: 0.1 μm) were used as starting materials, the composition was adjusted to Y:Fe=3.00:5.00 (molar ratio), the two components were wet-mixed in a ball mill, and the resulting mixed powder was CIP-molded (into a disk shape with a diameter of 40 mm and a thickness of 35 mm) at a pressure of 98 MPa. The pressed body was HIP-molded (pressure: 147 MPa) at 1210° C. with a mixed gas composition comprising 20% oxygen and 80% Ar. The resulting sintered body comprised uniform YIG (Y₃Fe₅O₁₂) grains of about 2 μm, and the relative density of the sintered body was 99.99%. The (111) plane of an YIG single crystal fabricated as a seed crystal by a flux technique was cut, and this plane was specularly finished to an average surface roughness Ra of 0.2 nm and a flatness of λ₂/4. A polycrystal obtained by HIP sintering in the same manner as above was also specularly finished in the same manner as above to an average surface roughness Ra of 0.2 nm and a flatness of λ₂/4, the two polished surfaces of the seed crystal and polycrystal were washed with acetone, and the polished surfaces of the two were superposed onto each other. The materials were kept for 16 hours in an oxygen atmosphere at 1480° C. while this state was maintained, and a single crystal was grown under non-melting conditions. The mean temperature gradient during crystal growth was kept at 25° C./cm. After the growth procedure, the polycrystal had become a single crystal to a depth of about 29 mm from the surface bonded to the single crystal. Based on these results, it was concluded that the growth rate was 1.8 mm/h and that growth could be performed at a much higher rate than the growth rate of the conventional melting and solidification technique. The density of grains that had formed low-angle tilt boundaries in the resulting YIG single crystal was 5 grains/cm², the dislocation density, excluding the low-angle tilt boundaries, was 5×10⁴ dislocations/cm², the refractive index distribution was 3×10⁻³, and the pore volume was 0.01 vol. ppm.

Embodiment 7

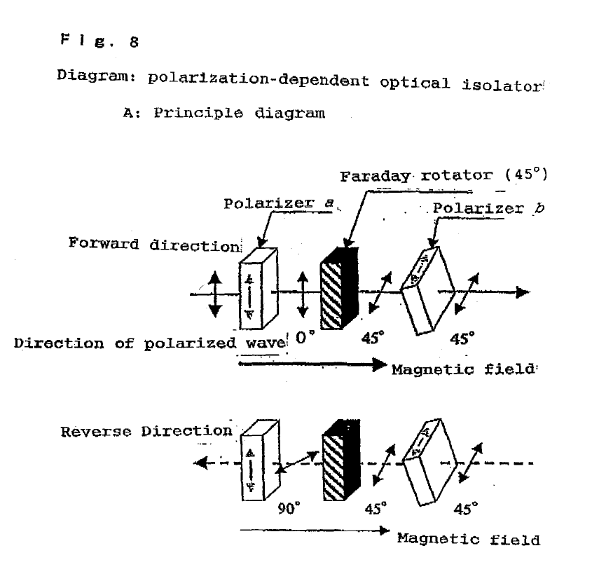

α-Fe₂O₃ powder (mean particle diameter: 0.8 μm), Tb₂O₃ powder (mean particle diameter: 0.3 pμ), and Bi₂O₃ powder (mean particle diameter: 0.3 μm) were used as starting materials, the composition was adjusted to (Tb+Bi):Fe=3.00:5.002 (molar ratio), and the two components were wet-mixed in a ball mill. The resulting mixed powder was CIP-molded (into a disk shape with a diameter of 40 mm and a thickness of 30 mm) at a pressure of 98 MPa. The shaped body was HIP-molded (pressure: 98 MPa) at 1220° C. with a mixed gas composition-comprising 20% oxygen and 80% Ar. The resulting sintered body comprised uniform (BiTb)₃Fe₅O₁₂ grains (composition: Bi_{0.5}Tb_{2.5}Fe₅O₁₂) of about 3 μm, and the relative density of this sintered body was 99.98%. The sintered body was heated to 900° C. in an electric furnace, and this sintered body was further irradiated for 30 minutes with light from a CO₂ laser with an output of 5 W (beam diameter: a circle with a diameter of 0.1 mm; laser energy density: about 1.6×10⁴ W/cm²). Following irradiation, the temperature of the electric furnace was raised to 1270° C., and the system was kept at this temperature for 24 hours and then cooled to room temperature. The mean temperature gradient during crystal growth was kept at 25° C./cm. FIG. 4 shows the results of observing the surface texture of the single crystal. The crystal growth proceeded radially, centered around the portion (seed crystal) irradiated with the CO₂ laser, as shown in FIG. 7. The size of the grown single crystal corresponded to a diameter of 30 mm and a thickness of 27 mm. Based on these results, it was concluded that the growth rate was 1.1 mm/h and that growth could be performed at a much higher rate than the growth rate of the conventional melting and solidification technique. The resulting (BiTb)₃Fe₅O₁₂ single crystal did not have any low-angle tilt boundaries and had a dislocation density of 1×10 dislocations/cm², a refractive index distribution of 1×10⁻⁴, and a pore volume of 15 vol. ppm.

Embodiment 8

α-Fe₂O₃ powder (mean particle diameter: 0.5 μm), Tb₂O₃ powder (mean particle diameter: 0.1 μm), and Gd₂O₃ powder (mean particle diameter: 0.2 μm) were used as starting materials, the composition was adjusted to Tb+Gd:Fe=3.00:5.01 (molar ratio), 0.8 wt % of flux (50 wt % Bi₂O₃, 40 wt % PbO, 10 wt % B₂O₃) was further added, the starting materials were wet-mixed in a ball mill, and the resulting mixed powder was CIP-molded (into a disk shape with a diameter of 25 mm and a thickness of 30 mm) at a pressure of 98 MPa. The formed body was subsequently baked for 5 hours in an oxygen atmosphere at 1300° C. The resultant body was further hot-pressed at 1290° C. and 147 MPa, yielding a sintered body having a grain size of about 6 μm and a relative density of 99.8%. A commercially available (CdCa)₃(CaMgZr)₅O₁₂ nonmagnetic garnet single crystal (crystal direction; <111>) prepared by the CZ technique was used as the seed crystal, and the surfaces of the seed crystal and the sintered body were specularly finished to an average surface roughness Ra of 0.2 n=and a flatness of λ/8. The two polished surfaces of the seed crystal and polycrystal were washed with acetone, and the polished surfaces of the two were superposed onto each other. In this case, an Fe(NO₃) aqueous solution was applied to the contact surfaces of the two. The materials were kept for 15 hours in an oxygen atmosphere at an average temperature of 1460° C. (since the temperature was raised from 1400 to 1500° C. over a period of 15 hours, the rate was 6.7° C./h) while this state was maintained, and a single crystal was grown under non-melting conditions. The mean temperature gradient during crystal growth was kept at 30° C./cm. After the growth procedure, the polycrystal had become a single crystal to a depth of about 23 mm from the surface bonded to the single crystal. Based on these results, it was concluded that the growth rate was 1.5 mm/h and that growth could be performed at a much higher rate than the growth rate of the conventional melting and solidification technique. The resulting YIG single crystal did not have any low-angle tilt boundaries and had a dislocation density of 1×10³ dislocations/cm², a refractive index distribution of 1×10⁻⁴, and a pore volume of 3 vol. ppm. In addition, the basic chemical formula of the single crystal was (Tb_{1.5}Gd_{1.5)Fe}₅O₁₂, but because a small amount of flux had been added when the sintered body was fabricated, 0.3 wt % B₂O₃ and 0.05 wt % PbO were detected (it was impossible to detect B₂O₃) in the single crystal by fluorescent x-ray analysis and plasma emission analysis.

Embodiment 9

α-Fe₂O₃ powder (mean particle diameter: 0.5 μm), Al₂O₃ powder (mean particle diameter: 0.3 μm), Ga₂O₃ powder (mean particle diameter: 0.5 μm), Bi₂O₃ powder (mean particle diameter: 0.1 μm), and Gd₂O₃ powder (mean particle diameter: 0.3 μm) were used as starting materials; the composition was adjusted to Bi+Gd:Fe+Al+Ga=3.00:5.00 (molar ratio): 0.1 wt % of flux (SiO₂) was further added; the starting materials were wet-mixed in a ball mill; and the resulting mixed powder was CIP-molded (into a disk shape with a diameter of 25 mm and a thickness of 35 mm) at a pressure of 98 MPa. The pressed body was fired for 5 hours in an oxygen atmosphere at 1230° C. The fired body was further hot-pressed at 1220° C. and 147 MPa, yielding a sintered body with a grain size of about 10 μm and a relative density of 99.6%. A commercially available (GdCa)₃(GaMgZr)₅O₁₂ nonmagnetic garnet single crystal (crystal direction: <111>) produced by the CZ technique was used as the seed crystal, and the surfaces of the seed crystal and the sintered body were specularly finished to an average surface roughness Ra of 0.2 nm and a flatness of λ/8. The two polished surfaces of the seed crystal and polycrystal were washed with acetone, and the polished surfaces of the two were superposed onto each other. In this case, an FeCl₃ aqueous solution was applied to the contact surfaces of the two. The materials were kept for 15 hours in an oxygen atmosphere at an average temperature of 1310° C. (since the temperature was raised from 1280 to 1340° C. over a period of 15 hours, the rate was 4.0° C./h) while this state was maintained, and a single crystal was grown under non-melting conditions. The mean temperature gradient during crystal growth was kept at 40° C./cm. After the growth procedure, the polycrystal had become a single crystal to a depth of about 21 mm from the surface bonded to the single crystal. Based on these results, it was concluded that the growth rate was 1.4 mm/h and that growth could be performed at a much higher rate than the growth rate of the conventional melting and solidification technique. The resulting single crystal did not have any low-angle tilt boundaries and had a dislocation density of 5×10³ dislocations/cm², a refractive index distribution of 5×10⁻⁴, and a pore volume of 5 vol. ppm. In addition, the basic chemical formula of the single crystal was (Bi_{0.30}Gd_{2.70})Fe_{3.5}Al_{0.5}Ga_{1.0}O₁₂ but because a small amount of flux had been added when the sintered body was produced. 0.01 wt % SiO₂ was detected in the single crystal by plasma emission analysis, indicating that most of the impurities were concentrated in the portion that had failed to convert to a single crystal.

Embodiment 10

a-Fe₂O₃ powder (mean particle diameter; 0.5 μm), Tb₂O₃ powder (mean particle diameter: 0.2 μm), and Bi₂O₃ powder (mean particle diameter: 0.1 μm) were used as starting materials, the composition was adjusted to Bi+Gd:Fe=3.00:5.01 (molar ratio), 0.5 wt % of flux (40 wt % Bi₂O₃, 40 wt % PbO, 20 wt % SiO₂) was further added, the starting materials were wet-mixed in a ball mill, and the resulting mixed powder was CIP-molded (into a disk shape with a diameter of 25 mm and a thickness of 30 mm) at a pressure of 98 MPa. The shaped body was baked for 3 hours in an oxygen atmosphere at 980° C. The sintered body was further hot-pressed at 900° C. and 147 MPa, yielding a sintered body with a grain size of about 8 μm and a relative density of 99.3%. A commercially available (GdCa)₃(GaMgZr)₅O₁₂ nonmagnetic garnet single crystal (crystal direction: <111>) prepared by the CZ technique was used as the seed crystal, and the surfaces of the seed crystal and the sintered body were specularly finished to an average surface roughness Ra of 0.2 nm and a flatness of λ/4. The two polished surfaces of the seed crystal and polycrystal were washed with acetone, and the polished surfaces of the two were superposed onto each other. The materials were kept for 20 hours in an oxygen atmosphere at an average temperature of 1030° C. (since the temperature was raised from 1000 to 1060° C. over a period of 20 hours, the rate was 3.0° C./h) while this state was maintained, and a single crystal was grown under non-melting conditions. The mean temperature gradient during crystal growth was kept at 15° C./cm. After the growth procedure, the polycrystal had become a single crystal to a depth of about 20 mm from the surface bonded to the single crystal. Based on these results, it was concluded that the growth rate was 1.0 mm/h and that growth could be performed at a much higher rate than the growth rate of the conventional melting and solidification technique. The resulting single crystal did not have any low-angle tilt boundaries and had a dislocation density of 5×10² dislocations/cm², a refractive index distribution of 5×10⁻⁴, and a pore volume of 8 vol. ppm. In addition, the basic chemical formula of the single crystal was (Bi_{1.5}Gd_{1.5})Fe₅O₁₂ but because a small amount of flux had been added when the sintered body was prepared. 0.005 wt % SiO₂ and 0.03 wt % PbO were detected in the single crystal by plasma emission analysis (the Bi in the flux was an element of the single crystal matrix, and was therefore undetectable).

Embodiment 11

The composition was adjusted to Dy:Fe=3.00:5.01 by coprecipitation, and wet mixing was performed to prepare a DIG (basic chemical formula: Dy₃Fe₅O₁₂) powder with a mean particle diameter of 0.5 μm. The powder was analyzed by powder x-ray diffraction and found to be a mixed phase containing garnet, perovskite, and the like. The mixed powder was CIP-molded (into a disk shape with a diameter of 30 mm and a thickness of 25 mm) at a pressure of 98 MPa. The shaped body was baked for 5 hours in an oxygen atmosphere at 1200° C. The resulting sintered body comprised uniform DIG grains of about 7 μm, and the relative density of this sintered body was 99.8%. The (111) plane of an YIG single crystal fabricated as a seed crystal by a floating zone technique was cut, and this plane was specularly finished to an average surface roughness Ra of 0.2 nm and a flatness of λ₂/4. A sample sintered at normal pressure was also specularly finished in the same manner as above to an average surface roughness Ra of 0.2 nm and a flatness of λ₂/4, the two polished surfaces of the seed crystal and polycrystal were washed with acetone, and the polished surfaces of the two were superposed onto each other. An HNO₃ aqueous solution was applied to the contact surfaces of the two. The materials were kept for 16 hours in an oxygen atmosphere at 1350° C. while this state was maintained, and a single crystal was grown under non-melting conditions. The mean temperature gradient during crystal growth was kept at 25° C./cm. In the process, the laminated single crystal (5 mm×5 mm×1 mm thickness) was continuously irradiated with light from a semiconductor laser (beam spot diameter: 3 mm, laser energy density: 71 W/cm²) with an output of 5 W and a wavelength of 780 nm. After the growth procedure, the polycrystal had become a single crystal to a depth of about 23 mm from the surface bonded to the single crystal. Based on these results, it was concluded that the growth rate was 1.4 mm/h and that growth could be performed at a much higher rate than the growth rate of the conventional melting and solidification technique. The density of crystal grains that had formed low-angle tilt boundaries with small inclination in the resulting DIG single crystal was 10 grains/cm², the dislocation density, excluding the low-angle tilt boundaries, was 5×10³ dislocations/cm², the refractive index distribution was 1×10⁻⁵, and the pore volume was 150 vol. ppm,

### REFERENCE EXAMPLE 1

The same Y₂O₃ powder and Fe₂O₃ powder as in embodiment 1 were used, the composition was adjusted to Y:Fe=3.00:4.98, wet mixing was performed, the mixed powder was CIP-molded (into a disk shape with a diameter of 16 mm and a thickness of 10 mm) at a pressure of 98 MPa, and the molding was baked for 10 hours at 1320° C. No coarse YIG (Y₃Fe₅O₁₂) grains had formed in the sintered body, and a fine structure that comprised uniform grains measuring about 5 μm was obtained.

The (111) plane of an YIG single crystal fabricated as a seed crystal by a flux technique was cut, and this plane was specularly finished to an average surface roughness Ra of 0.2 nm and a flatness of λ₂/4. A mixed powder with the same composition was also molded in the same manner into a disk shape and subjected to hot press sintering (pressure: 9.8 MPa) for 3 hours at 1250° C. in the atmosphere, yielding polycrystalline YIG (diameter: 30 mm, thickness: 25 mm) with a relative density of 99.7% The end face of the polycrystal was specularly finished to an average surface roughness Ra of 0.2 nm and a flatness of λ₂/4. The two polished surfaces of the seed crystal and polycrystal were washed with acetone, and the polished surfaces of the two were superposed onto each other. The materials were kept for 20 hours in an oxygen atmosphere at 1420° C. while this state was maintained, and a single crystal was grown under non-melting conditions. After the growth procedure, a single crystal conversion occurred to a depth of only about 500 μm from the surface bonded to the single crystal. Based on these results, it was concluded that the growth rate was 2.5×10⁻² mm/h, which was much lower than the growth rate of the conventional melting and solidification technique.

### REFERENCE EXAMPLE 2

The same Y₂O₃ powder and Fe₂O₃ powder as in embodiment 1 were used, the composition was adjusted to Y:Fe=3.00:5.08, wet mixing was performed, the mixed powder was CIP-molded (into a disk shape with a diameter of 16 mm and a thickness of 10 mm) at a pressure of 98 MPa, and the molding was baked for 10 hours at 1320° C. in an oxygen atmosphere. The sintered body contained structures with a wide grain size distribution, from several micrometers to several hundred micrometers. It was also confirmed that an Fe₂O₃ phase had precipitated on the periphery of the grains and that the product was not a uniform YIG phase.

The (111) plane of an YIG single crystal fabricated as a seed crystal by a flux technique was cut, and this plane was specularly finished to an average surface roughness Ra of 0.2 nm and a flatness of λ₂/4. A mixed powder with the same composition was also molded in the same manner into a disk shape and subjected to hot press sintering (pressure: 9.8 MPa) for 3 hours at 1220° C., yielding polycrystalline YIG (diameter: 30 mm, thickness: 25 mm) with a relative density of 99.7%. The end face of the polycrystal was specularly finished to an average surface roughness Ra of 0.2 nm and a flatness of λ₂/4. The two polished surfaces of the seed crystal and polycrystal were washed with acetone, and the polished surfaces of the two were superposed onto each other. The materials were kept for 20 hours in an oxygen atmosphere at 1420° C. while this state was maintained, and a single crystal was grown under non-melting conditions. After the growth procedure, a single crystal conversion occurred to a depth of only about 500 μm from the surface bonded to the single crystal. In addition, portions other than the single crystal represented a large polycrystal measuring about 300 μm. Based on these results, it was concluded that the growth rate was 2.5×10⁻² mm/h, which was much lower than the growth rate of the conventional melting and solidification technique. A sample manufactured in the same manner by extending the heat treatment time to 500 hours was studied separately, and it was confirmed that the growth domain of the single crystal had changed only slightly from that of the aforementioned sample.

### COMPARATIVE EXAMPLE 1

An YIG single crystal was grown by the floating zone technique.

A sintered body (diameter: 10 mm, length: 100 mm) was produced using a commercially available YIG powder, and the sintered body was introduced into an apparatus and partially melted using an infrared lamp. A single crystal with the <111>direction was used as the seed crystal, the growth (melting) temperature was set to 1580° C., and a condensing beam was moved at a speed of 0.4 mm/h from a reflecting plate to perform crystal growth. The growth was completed about 200 hours later, that is, when the crystal length reached 80 mm. The resulting crystal had a diameter of 10 mm and a length of 80 mm (capacity: 6.3 cm³). The dislocation density of the crystal interior was high, at 5×10⁶ dislocations/cm³, and it was impossible to detect any low-angle tilt boundaries because of the excessively high dislocation density. The refractive index distribution was 8×10⁻³. In addition, the productivity was 0.032 cm³/h, which was low, at about 1/500 of the productivity achieved in embodiment 4.

### COMPARATIVE EXAMPLE 2

A (BiTb)IG single crystal was grown by LPE.

Commercially available Bi₂O₃, Tb₂O₃, and Fe₂O₃ powders were used as starting materials, an appropriate amount of PbO—Bi₂O₃ flux was added thereto, the materials were melted in a platinum crucible, soaking was performed for 3 hours at 1100° C., and the product was cooled to supersaturation. A <111> 3-inch GGG water that had been doped with small amounts of Ca, Mg, and Zr in order to reduce the lattice mismatch with a magnetic (BiTb) IG single crystal was immersed in the supersaturated melt, and a (BiTb) IG single-crystal thick film was allowed to grow on the wafer. The growth temperature was 920° C., and a 0.6-mm (Bi_{0.95}Tb_{2.05})Fe₅O₁₂ single-crystal thick film was formed on the GGG wafer over a period of about 80 hours. The density of the crystal grains that had formed low-angle tilt boundaries was 120 grains/cm², and the dislocation density, excluding the low-angle tilt boundaries, was 5×10³ dislocations/cm². The productivity was 0.033 cm³/h because a magnetic film with a thickness of 0.6 mm was deposited on the 3-inch wafer. The productivity was extremely low, at about 3/1000 of embodiment 5, in which a single crystal with a similar composition was manufactured.

### COMPARATIVE EXAMPLE 3

The same α-Fe₂O₃ powder (mean particle diameter; 0.8 μm) and Y₂O₃ powder (mean particle diameter: 0.1 μm) as in embodiment 1 were used as starting materials, the composition was adjusted to Y:Fe=3.00:5.01 (molar ratio), the two components were wet-mixed in a ball mill, and the resulting mixed powder was CIP-molded at a pressure of 98 MPa. The molding was subsequently subjected to hot press sintering for 3 hours in an oxygen atmosphere at 1250° C. and 9.8 MPa, yielding polycrystalline YIG (diameter: 30 mm, thickness: 25 mm) with a relative density of 99.5%. Both the end face of the polycrystal and a seed crystal (YIG <111> single crystal fabricated by FZ) were specularly finished to an average surface roughness Ra of 0.2 nm and a flatness of λ₂/4, the two polished surfaces of the seed crystal and polycrystal were washed with acetone, and the polished surfaces of the two were superposed onto each other. The materials were kept for 20 hours in an oxygen atmosphere at an average temperature of 1370° C. (since the temperature was raised from 1350 to 1390° C. over a period of 20 hours, the temperature increase rate was 2° C./h) while this state was maintained, and a single crystal was grown under non-melting conditions. In this case, a MgO sinter was used as the heat sink material in the same manner as in embodiment 1. However, the growth treatment was performed in a soaking furnace without any forced cooling from below. For this reason, the mean temperature gradient during crystal growth was 0° C./cm. After the growth procedure, the polycrystal had become a single crystal to a depth of about 8 mm from the surface bonded to the single crystal, but when a cross section of the single crystal in the growth direction was examined, it was found that crystals that had different directions and measured 0.5 to 1.0 mm in terms of diameter had grown inside the single crystal. A relatively large number of air pockets was confirmed to have remained in the grown single crystal and on the periphery of the crystals with different directions, and the amount thereof was about 17 times greater than in embodiment 1. Coarse crystals with diameters in the 1-mm category were found to have formed at a distance of 8 mm and greater from the surface bonded to the seed crystal, and the formation of a single crystal was found to have been interrupted. The density of the crystal grains that had formed low-angle tilt boundaries in the crystal was 1×10³ grains/cm²; the dislocation density, excluding the low-angle tilt boundaries, was 5×10⁵ dislocations/cm²: the refractive index distribution was 5×10⁻³; and the pore volume was 510 vol. ppm. The magnetic garnet single crystal thus obtained had low optical quality and was unsuitable for isolators.

### COMPARATIVE EXAMPLE 4

α-Fe₂O₃ powder (mean particle diameter: 0.8 μm), Tb₂O₃ powder (mean particle diameter: 0.3 μm), and Bi₂O₃ powder (mean particle diameter: 0.3 μm) were used as starting materials in the same manner as in embodiment 2, the composition was adjusted to (Tb+Bi);Fe=3.00:5.01 (molar ratio), the two components were wet-mixed in a ball mill, and the resulting mixed powder was CIP-molded (into a rod shape with a diameter of 16 mm and a thickness of 60 mm) at a pressure of 98 MPa. The molding was subjected to hot press sintering (pressure: 19.6 MPa) for 3 hours in an oxygen atmosphere at 1220° C. and a polycrystal (composition: Bi_{0.5}Tb_{2.5}Fe₅O₁₂) with a relative density of 99.9% was obtained. A commercially available (GdCa)₃(GaMgZr)₅O₁₂ nonmagnetic garnet single crystal (crystal direction: <111>) fabricated by the CZ technique was used as the seed crystal, and the seed crystal and the sintered body were specularly finished to an average surface roughness Ra of 0.2 nm and a flatness of λ₂/6. The two polished surfaces of the seed crystal and polycrystal were washed with acetone, and the seed crystal and the polycrystal were joined together by being heated for 1 hour (under a load of 1 kg) to 1250° C. while the polished surfaces of the two were superposed onto each other. The bonded sample was subjected to a growth treatment in a two-zone furnace controlled to 1240° C. and 1320° C. The sample was first introduced into the part of the furnace controlled to 1240° C., and was then introduced at a rate of 0.5 mm/h from the side of the seed crystal into the part of the furnace controlled to 1320° C. Thermocouples were mounted in advance on the side of the seed crystal and on the side facing the seed crystal, and ΔT was measured when the sample reached the center of the two-zone furnace, whereupon it was found that the temperature difference was 30° C. (at a sample length of 50 mm), and that the mean temperature gradient in the material was therefore 6° C./cm. The pulling time was about 100 hours because the crystal growth was set to complete the moment the entire sample was inside the furnace on the high-temperature side.

After the growth procedure, the polycrystal had become a single crystal to a depth of about 13 mm from the surface bonded to the single crystal. When a cross section in the single crystal was examined in the same manner as in embodiment 3, it was found that crystals that had different directions and measured 0.5 to 3.0 mm in terms of diameter had grown inside the single crystal, and that about 90 times the number of residual air pockets observed in embodiment 2 were present in the entire crystal and on the periphery of the crystals with different directions. It was also confirmed that coarse crystals measuring 0.1 to 3 mm had grown in areas no less than 13 mm from the seed crystal and that no single crystals had formed there. A simple calculation of the time required by the crystal growth domain was performed, and it was found that the growth rate was 0.13 mm/h and that the crystal quality and productivity were much lower than in embodiment 2. The density of the crystal grains that had formed low-angle tilt boundaries in the resulting (BiTb)₃Fe₅O₁₂ single crystal was 1×10³ grains/cm²; the dislocation density, excluding the low-angle tilt boundaries, was 5×10⁴ dislocations/cm²; the refractive index distribution was 3×10⁻³: and the pore volume was 450 vol. ppm. Thus, the resulting magnetic garnet single crystal had low optical quality and was unsuitable for isolators.

### TEST EXAMPLE 1

The magneto-optics characteristics of the present-invention single crystal and conventional single crystals were studied. The results are shown in Table 1. In Table 1, samples A to D designate the magnetooptical characteristics of single crystals fabricated in accordance with the present invention, and samples E to F (comparison samples) designate magnetooptical characteristics of single crystals grown by the LPE and FZ techniques.

A comparison of the two types indicates that the present-invention single crystal has about the same excellent magnetooptical characteristics as those provided by the conventional techniques.

Samples C and D indicate the characteristic values of magnetic garnet crystals with 20 molt and 50 mol % substitutions, which are the Bi addition ranges in which addition is difficult to accomplish by the prior art technology. It can be seen that samples C and D have exceptionally high Faraday rotation angles. It can thus be seen that the present-invention single crystal can be used in optical isolators.

TABLE 1

| | | | | |
|---|---|---|---|---|
| External | | | Hate of | |
| magnetic | | | temperature | |
| field | | Faraday | change | |
| strength to | Measurement | rotation | of Faraday | |
| saturation | wavelength | coefficient | rotation | Insertion |
| (Oe) | λ (nm) | (deg./cm) | angle | loss (dB) |

Samples A) to D)

| | | | | | |
|---|---|---|---|---|---|
| A) Y₃Fe₅O₁₂ | 1800 | 1300 | 260 | 0.060 | 0.4 |
| B) (Tb_{2.5} | 830 | 1300 | 1240 | 0.075 | 0.5 |
| Bi_{0.5})Fe₅ | | | | | |
| O₁₂ | | | | | |
| C) (Tb_{1.0} | 1700 | 1300 | 2450 | 0.080 | 0.4 |
| Gd_{1.0}Bi_{1.0}) | | | | | |
| Fe₅O₁₂ | | | | | |
| D) Bi_{1.7} | 1250 | 1300 | 4300 | 0.085 | 0.3 |
| Gd_{0.8}Y_{0.5} | | | | | |
| Fe_{4.0}Ga_{1.0} | | | | | |
| O₁₂ | | | | | |

Samples E) to F)

| | | | | | |
|---|---|---|---|---|---|
| E) (TbBi)₃ | 800 | 1300 | 1250 | 0.074 | 0.4 |
| (FeAlGa)₅ | | | | | |
| F) Y₃Fe₃O₁₂ | 1800 | 1300 | 250 | 0.060 | 0.9 |

*In sample A), Mn is added in an amount of 0.3 mol % in relation to Fe
Sample E) is a thick film formed on GGG<lll> wafer by LPE method
Sample F) is a single crystal with a diameter of 6 mm and a length of 50 mm prepared by FZ method

Fabrication Example of Isolation Module

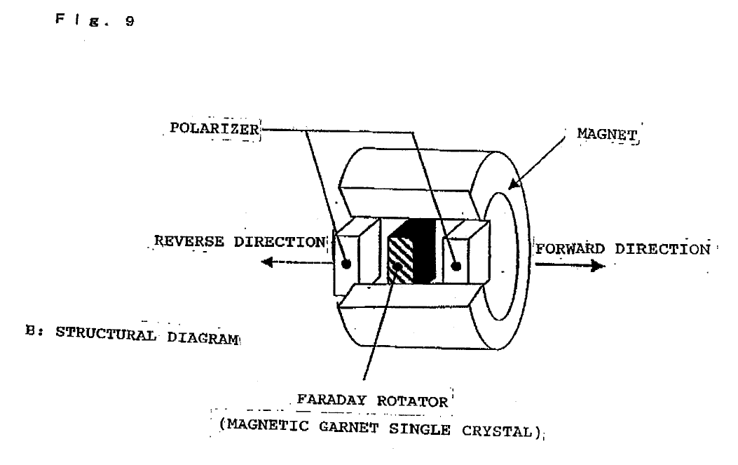

FIG. 8 depicts the principle of a polarization-dependent optical isolator.

A polarization-dependent optical isolator is configured such that AR (antireflecting) films are formed on both end faces of a single crystal that has been optically polished to a thickness at which the Faraday rotation angle thereof is equal to 45 degrees, and polarizers a and b are set up such that polarizer a has a polarization dimension of 45 degrees and polarizer b has a direction of 90 degrees, that the semiconductor laser light of the forward direction alone is allowed to pass, and that any returning wave (reflected wave) is shut out by polarizer a. An isolator module may also be fabricated using a common element structure in which a permanent magnet needed to generate a magnetic field is mounted around the outside of a magnetic garnet single crystal. For example, the material is optically polished to a thickness of 1.73 mm when sample A of the present invention is used, and to a thickness of 0.18 mm when sample C is used, and an AR coating is formed on both sides of each sample.

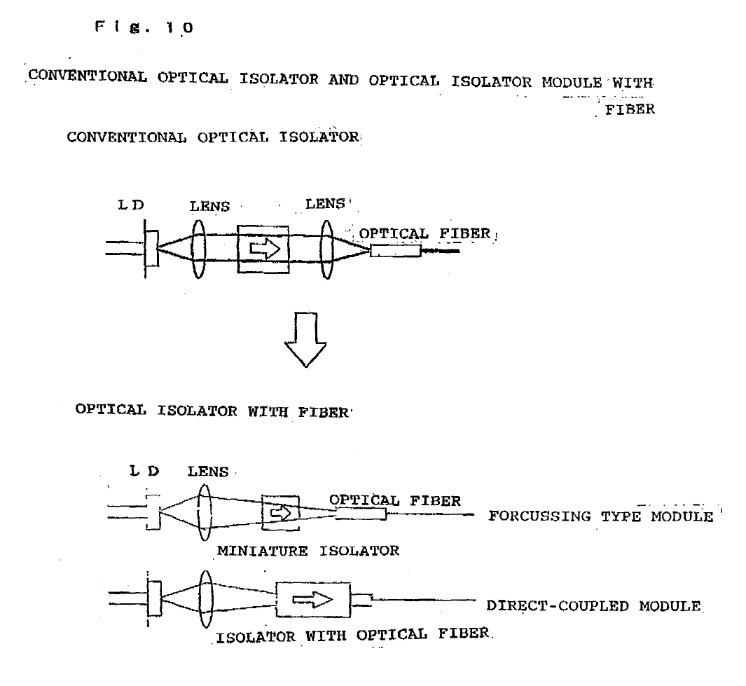

The sample (magnetic garnet single crystal) of the present invention was mounted in the main body to construct an optical isolator, as shown in FIG. 9. A semiconductor laser with a wavelength of 1.3 μm was introduced into the isolator, and the polarization angle of light obtained in the forward direction was measured using a polarizing plate. As a result, it was possible to confirm that an isolator obtained using sample A or C was able to polarize light by 45 degrees. This indicates that light can be polarized by another 45 degrees when a reflected wave arrives from the reverse direction during fiber optic communication, allowing the product to be used as an isolator.

FIG. 10 is a schematic of a conventional optical isolator module and an optical isolator module equipped with fiber. The present invention allows the optical (lens) system to be simplified by reducing to 50 mol % or less the amount in which Bi, which contributes to the increase in the Faraday rotation angle, is introduced into the magnetic garnet single crystal. For example, a total of two lenses is mounted in front of and behind an isolator element in order to introduce an optical fiber into the conventional type, whereas a single lens is sufficient for a focussing type module or a direct-coupled module, making it possible to miniaturize the isolator module. The present-invention single crystal may also be adapted to a magneto-optics sensor or the like.

1. A rare-earth iron garnet single crystal, substantially composed of an Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5), with the number n per unit surface area (grains/cm²) of crystal grains that form low-angle tilt boundaries equal to 0≦n<10².

2. A rare-earth iron garnet single crystal, substantially composed of an Re₃Fe₅₋ₓMₓO₁₂ single crystal (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5), with the dislocation density (excluding dislocations that form low-angle tilt boundaries) equal to 1×10⁵ dislocations/cm² or less.

3. The rare-earth iron garnet single crystal according to claim 1 or 2, wherein the pore volume is 200 vol. ppm or less.

4. The rare-earth iron garnet single crystal according to claim 1 or 2, wherein the refractive index distribution in the near-infrared wavelength region with wavelengths of 1.3 to 2.0 μm is 5×10⁻³ to 1×10⁻⁶.

5. The rare-earth iron garnet single crystal according to claim 1 or, 2, wherein the purity is 99.5 wt % or greater.

6. A method for manufacturing a rare-earth iron garnet single crystal substantially composed of an Re₃Fe₅₋ₓMₓO₁₂ single crystal by forming an oxide powder whose composition has an Re:Fe₅₋ₓMₓ molar ratio (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30: and 0≦x<5) of 3.00:4.99 to 5.05 into a shaped body, and heat-treating said shaped body or the sintered body thereof at 900 to 1500° C. to induce crystal growth,
wherein the shaped body or the sintered body is subjected to a mean temperature gradient of 10° C./cm or greater by performing at least one treatment selected from (a) heating the crystal growth start portion and (b) cooling an end part other than said portion during crystal growth.

7. The manufacturing method according to claim 6, wherein the oxide powder is a mixed powder comprising:
1) an Re oxide powder (where Re is at least one element selected from the group consisting of Y, Bi, Ca, and lanthanide rare-earth elements with atomic numbers of 62 to 71); and
2) (1) an iron oxide powder or (2) a powder composed of at least one element selected from the group consisting of Al, Ga, Sc, In, Sn and transition metal elements with atomic numbers of 22 to 30, and an iron oxide powder.

8. The manufacturing method according to claim 7, wherein
1) the primary particle diameter of the Re iron oxide powder (where Re is at least one element selected from the group of Y, Bi, Ca, and lanthanide rare-earth elements with atomic numbers of 62 to 71) is 20 to 500 nm, and the BET specific surface area is 5 to 50 m²/g; and
2) the primary particle diameter of (1) the iron oxide powder or (2) the powder composed of at least one material selected from the group consisting of aluminum oxide powder, gallium oxide powder, scandium oxide powder, indium oxide powder, tin oxide powder and oxide powders of transition metals with atomic numbers of 22 to 30, and an iron oxide powder is 100 to 1000 nm, and the BET specific surface area is 3 to 30 m²/g.

9. A method for manufacturing a rare-earth iron garnet single crystal substantially composed of an Re₃Fe₅₋ₓMₓO₁₂ single crystal by bringing an Re₃M₅O₁₂ or Re₃Fe₅₋ₓMₓO₁₂ single crystal into contact as a seed crystal with an Re₃Fe₅₋ₓMₓO₁₂ sintered body whose composition has an Re:Fe₅₋ₓMₓ molar ratio (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) of 3.00:4.99 to 5.05, and then performing a heat treatment at 900 to 1500° C. to induce crystal growth,
wherein the sintered body is subjected to a mean temperature gradient of 10° C./cm or greater by performing at least one treatment selected from (a) heating the seed crystal portion and (b) cooling an end part other than said portion during crystal growth.

10. The manufacturing method according to claim 9, wherein the Re₃Fe₅₋ₓMₓO₁₂ sintered body (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≧x<5) has a relative density of 99% or greater.

11. The manufacturing method according to claim 9, wherein the (100), (110), or (111) plane of an Re₃M₅O₁₂ or Re₃Fe₅₋ₓMₓO₁₂ single crystal (where Re is at least one element selected from the group consisting of X, Bi, Ca, and lanthanide rare-earth elements with atomic numbers of 62 to 71; M is at least one element selected from the group consisting of Al, Ga, Sc, In, Sn and transition metal elements with atomic numbers of 22 to 3, and 0≦x<5) is polished, and the polished plane is brought into contact with an Re₃Fe₅₋ₓMₓO₁₂ sintered body.

12. The manufacturing method according to claim 11, wherein the average surface roughness Ra of the polished plane is 1.0 nm or less, and the flatness λ is 633 nm or less.

13. The manufacturing method according to claim 9, wherein part or all of the Re₃Fe₅₋ₓMₓO₁₂ sintered body (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30: and 0≦x<5) is polished to an average surface roughness Ra of 1.0 nm or less and a flatness λ of 633 nm or less, and the polished plane is brought into contact with an Re₃M₅O₁₂ or Re₃Fe₅₋ₓO₁₂ single crystal.

14. The manufacturing method according to claim 9, wherein an aqueous solution containing at least one element selected from the group consisting of Re, Fe, and M is applied to at least one contact surface of the Re₃Fe₅₋ₓMₓO₁₂ sintered body (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30; and 0≦x<5) and the Re₃M₅O₁₂ or Re₃Fe₅₋ₓMₓO₁₂ single crystal.

15. A method for manufacturing a rare-earth iron garnet single crystal substantially composed of an Re₃Fe₅₋ₓMₓO₁₂ single crystal by irradiating with a laser beam an Re₃Fe₅₋ₓMₓO₁₂ sintered body whose composition has an Re:Fe₅₋ₓMₓ molar ratio (where Re is at least one element selected from the group consisting of Y, Bi, Ca, and lanthanide rare-earth elements with atomic numbers of 62 to 71; M is at least one element selected from the group consisting of Al, Ga, Sc, In, Sn and transition metal elements with atomic numbers of 22 to 30, and 0≦x<5) of 3.00:4.99 to 5.05 to form a seed crystal of an Re₃Fe₅₋ₓMₓO₁₂ single crystal, then performing a heat treatment at 900 to 1500° C. to induce crystal growth,
wherein the sintered body is subjected to a mean temperature gradient of 10° C./cm or greater by performing at least one treatment selected from (a) heating the seed crystal portion and (b) cooling an end part other than said portion during crystal growth.

16. The manufacturing method according to claim 15, wherein the wavelength of the laser beam is 0.2 to 11 μm (excluding the transmission wavelength of the Re₃Fe₅₋ₓMₓO₁₂).

17. The manufacturing method according to claim 15, wherein the irradiation area of the laser beam is 1 mm² or less.

18. The manufacturing method according to claim 15, wherein the Re₃Fe₅₋ₓMₓO₁₂ sintered body is irradiated with a laser beam while heated to less than 1300° C.

19. The manufacturing method according to claim 6, 9, or 15, wherein an oxide capable of forming a liquid phase during crystal growth is allowed to be present in the shaped body or the sintered body.

20. The manufacturing method according to claim 6, 9, or 15, wherein the temperature increase rate is kept at 50° C./h or less during crystal growth.

21. The manufacturing method according to claim 6, 9, or 15, wherein the cooling is performed by blowing a coolant onto the end portion.

22. The manufacturing method according to claim 6, 9, or 15, wherein the cooling is performed by pressing a heat sink material comprising a metal or an inorganic material against the end portion, and bringing a coolant into contact with the heat sink material.

23. The manufacturing method according to claim 6. 9, or 15, wherein the growth of the single crystal is controlled by varying (1) the temperature increase rate or (2) both the temperature increase rate and the coolant flow rate.

24. A device in which the rare-earth iron garnet single crystal according to claim 1 or 2 is used.
